(19) United States
(12) Patent Application Publication
(10) Pub. No.: US 2025/0074930 A1
(43) Pub. Date: Mar. 6, 2025

(54) ORGANOTIN COMPOSITIONS HAVING LIGANDS WITH ACETAL FUNCTIONAL GROUPS, PATTERNING COMPOSITIONS WITH ORGANOTIN BLENDS AND POSITIVE TONE PATTERNING

(71) Applicant: Inpria Corporation, Corvallis, OR (US)

(72) Inventors: Alexander C. Marwitz, Corvallis, OR (US); Kai Jiang, Corvallis, OR (US); Bryan T. Novas, Philomath, OR (US); Robert E. Jilek, Philomath, OR (US); Christopher J. Reed, Corvallis, OR (US); Brian J. Cardineau, Corvallis, OR (US); Munendra Yadav, Corvallis, OR (US)

(21) Appl. No.: 18/816,097

(22) Filed: Aug. 27, 2024

Related U.S. Application Data
(60) Provisional application No. 63/535,003, filed on Aug. 28, 2023.

(51) Int. Cl. C07F 7/22; C09K 11/06; G03F 7/004; G03F 7/20; G03F 7/32

(52) U.S. Cl. CPC C07F 7/2224; C09K 11/06; G03F 7/0042; G03F 7/0048; G03F 7/2004; G03F 7/32

(57) ABSTRACT

Organotin patterning compositions have radiation sensitive ligands with acetal functional groups. Precursor compositions are compositions comprising (OR⁴)(OR³)R²CR¹SnL₃, where the R groups are substituted or unsubstituted hydrocarbyl groups and L is a hydrolysable ligand. The precursors can be formed into coating that can be patterned with radiation, in particular EUV radiation. Coatings formed with blended precursors with hydrocarbyl-based ligands with some having acetal groups and others lacking acetal groups can be particularly effective for improving positive tone patterning.

### CROSS REFERENCE TO RELATED APPLICATIONS

This application claims priority to copending U.S. provisional patent application 63/535,003 filed Aug. 28, 2023 to Jilek et al., entitled “Organotin Compositions Having Ligands With Acetal Functional Groups,” incorporated herein by reference.

### FIELD OF THE INVENTION

The invention relates to organotin compounds with ligands having acetal functional groups and generally bound with C—Sn bonds. Invention further relates to radiation patternable compositions and corresponding coatings having blends of organotin compositions with a portion of the tin atoms having ligands with acetal groups. Positive tone patterning can be achieved with desirable performance using the organotin blends.

### BACKGROUND OF THE INVENTION

Organometallic compounds suitable for radiation based patterning can be provided with metal ions in solution or in vapor forms for deposition of thin films. Organotin compounds can provide high EUV absorption and radiation sensitive tin-ligand bonds that can be used to lithographically pattern thin films. The manufacture of semiconductor devices at ever shrinking dimensions with EUV radiation requires new materials with wide process latitude to achieve required patterning resolutions and low defect densities.

In general, patterning compositions are referred to as resists or photoresists since the compositions can be used for pattern transfer. The resist can be referred to as negative tone resists where irradiated material is maintained when forming a physical pattern, or as positive tone resists where the non-irradiated material is maintained in forming a physical pattern. Depending on the pattern shape desired, there can be advantages with respect to the selection of the resist tone for processing.

### SUMMARY OF THE INVENTION

### Problem to be solved

In order to have high process stability MOR resists, it is important to have high activation energy tin-carbon bond chemistry. In doing so however, photochemical sensitivity can suffer. Therefore, a high stability, high-sensitivity ligand approach is desired.

### Solution

New RSn ligands comprising acetal functional groups enables new exposure mechanisms of RSn resists driven by photochemistry on the R group rather than radiolysis of the R—Sn bond, and thereby opening up possible photoresist design space.

In one aspect, the invention pertains to organotin compounds having acetal functional groups represented by the formula L₃SnR¹R²C(OR³)(OR⁴), where R³ and R⁴ are independently substituted or unsubstituted hydrocarbyl groups having 1 to 4 carbon atoms, R² is hydrogen or a substituted or unsubstituted hydrocarbyl group having from 1 to 10 carbon atoms, R¹ is a substituted or unsubstituted hydrocarbyl group having from 1 to 15 carbon atoms and a Sn—C bond, and L is a hydrolysable ligand.

In another aspect, the invention pertains to organotin compounds having acetal functional groups represented by the formula L₃SnR¹R²C(O₂R³), where R³ is a hydrocarbyl groups having 1 to 6 carbon atoms, R² is hydrogen or a substituted or unsubstituted hydrocarbyl group having from 1 to 10 carbon atoms, R¹ is a substituted or unsubstituted hydrocarbyl group having from 1 to 15 carbon atoms and a Sn—C bond, and L is a hydrolysable ligand.

In a related aspect, the invention pertains to a composition comprising (OR⁴)(OR³)R²CR¹SnL₃, wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, wherein R³ and R⁴ are independently substituted or unsubstituted hydrocarbyl groups having 1 to 4 carbon atoms or wherein R³ and R⁴ collectively form a bridging structure —OR⁵O—(R⁵=R³+R⁴) where R⁵ is a hydrocarbyl group having 1 to 10 carbon atoms and forms a cyclic linkage between the acetal O atoms, and L is a hydrolysable ligand. A precursor solution can comprise the composition in an organic solvent.

In another aspect, the invention pertains to a blended composition comprising two or more organotin compositions wherein at least one organotin composition has an acetal functional group. One composition can be described in the preceeding paragraph, and the other composition represented by the formula (R^{a})SnL′₃, or a combination thereof, and wherein R^{a} is a substituted or unsubstituted hydrocarbyl ligand with 1 to 30 carbon atoms and an Sn—C bond, and L′ is a hydrolysable ligand that is the same or different from L.

In a further aspect, the invention pertains to a coated substrate comprising a substrate, and an organotin coating on the surface of the substrate, in which the organotin coating comprises an oxo-hydroxo network having incorporated organotin moieties represented by the formula (OR⁴)(OR³)R²CR¹Sn wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently substituted or unsubstituted hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms.

In some aspects, the invention pertains to a precursor solution for depositing a patterning composition, the precursor solution comprising:
an organic solvent,
a first tin precursor composition represented by the formula (OR⁴)(OR³)R²CR¹SnL₃ wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, and L is a hydrolysable ligand, and
a second tin precursor composition represented by the formula R^{a}SnL′₃, R^{a} is a substituted or unsubstituted hydrocarbyl ligand with 1 to 30 carbon atoms, and L′ is a hydrolysable ligand that is the same or different from L.

In additional aspects, the invention pertains to a method for patterning a coated substrate having a virtual image formed with patterned EUV radiation comprising a substrate and an organotin coating on the surface of the substrate, the organotin coating comprising non-irradiated portions and irradiated portions,
wherein the non-irradiated portions comprise a patternable composition comprising an oxo-hydroxo network having incorporated organotin moieties represented by the formula (OR⁴)(OR³)R²CR¹Sn, wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, the method comprising:
contacting the coating on the surface of the substrate with an aqueous liquid to substantially remove the irradiated portions while maintaining the non-irradiated portions substantially intact.

In other aspects, the invention pertains to a method for patterning a coated substrate having a virtual image formed with patterned EUV radiation comprising a substrate and an organotin coating on the surface of the substrate, the organotin coating comprising non-irradiated portions and irradiated portions,
wherein the non-irradiated portions comprise a patternable composition comprising an oxo-hydroxo network having incorporated organotin moieties represented by the formula (OR⁴)(OR³)R²CR¹Sn, wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, the method comprising:
contacting the coating on the surface of the substrate with an organic liquid to substantially remove the non-irradiated portions while maintaining the irradiated portions substantially intact.

Moreover, the invention pertains to a method for synthesizing a substituted 1,3-benzodioxole compound, the method comprising:
reacting a catechol in an organic solvent with hexamethylsilazne to form an intermediate; and
reacting the intermediate in an organic solvent with a ketone or an aldehyde in the presence of trimethylsilyl trifluoromethanesulfonate catalyst to form a substituted 1,3-benzodioxole.

Additionally, the invention pertains to a compound being a halogen substituted 2-alkyl-1,3-benzodioxole with optional additional substitutions represented by the formula C₆R^{a}R^{b}R^{c}R^{d}O₂CR¹R², wherein R¹ is a substituted or unsubstituted hydrocarbyl group having from 1 to 15 carbon atoms, R² is hydrogen or a substituted or unsubstituted hydrocarbyl group having from 1 to 10 carbon atoms.

### BRIEF DESCRIPTION OF THE DRAWINGS

FIG. 1 is a schematic drawing depicting an organotin composition with acetal functionality undergoing various possible reactions triggered by energy absorption from radiation.

FIG. 2A is a schematic drawing depicting hypothetical radical intermediates from FIG. 1 reacting to form a dimerized product.

FIG. 2B is a schematic drawing depicting a hypothetical radical intermediate from FIG. 1 reacting with an organotin composition with olefinic functionality to form a polymerized product.

FIG. 3 is a plot of normalized FTIR peak areas as a function of bake temperature for three organotin compositions with acetal functionality and two organotin compositions without acetal functionality.

FIG. 4 is a plot of contrast curves for coated wafers that were prepared from either a resist solution incorporating acetal functional group (curves A and B) or a resist solution absent acetal functional groups (curve CE1) and then subjected to a post-exposure bake (PEB) at 100° C.

FIG. 5 is a plot of contrast curves for coated wafers that were prepared from either a resist solution incorporating acetal functional groups (curves A and B) or a resist solution absent acetal functional groups (curve CE1) and then subjected to a PEB at 120° C.

FIG. 6 is a plot of contrast curves for coated wafers that were prepared from a resist solution incorporating fluorinated ligands and acetal functional groups (curve C) or a resist solution incorporating fluorinated ligands and absent acetal functional groups (curve CE2) and then subjected to a PEB at 100° C.

FIG. 7 is a set of contrast curves for coated wafers that were prepared from a resist solution incorporating acetal functional groups and then subjected to different post-exposure bake temperatures: 100° C. or 140° C.

FIG. 8 is a set of contrast curves for coated wafers that were prepared from a resist solution incorporating acetal functional groups and then subjected to different hardbake conditions: 100° C., 150° C., 200° C. or no hardbake.

FIG. 9 is a CD-SEM image of a contact hole pattern formed by EUV radiation of a photoresist coating prepared from a resist solution incorporating acetal functional groups.

### DETAILED DESCRIPTION

New organotin photoresist compositions comprising organic ligands having acetal functionality have been synthesized. These new compositions can be effective to provide complementary properties for precursor blends to enhance useful process windows, especially with respect to irradiation dose and contrast for positive tone patterning. Some organotin embodiments may have usefulness in blends for negative tone patterning. The compositions also provide enhanced thermal stability for the blended precursor compositions yet allow for an opening of the positive tone process window as a function of dose. As demonstrated herein, some embodiments of the organotin precursors with acetal ligands exhibit good solubility in a wide range of solvents, aqueous and organic. As a result of broad solubility, the acetal ligand tin precursors can enable new blended compositions with improved capabilities for positive tone patterning. Aromatic versions of the acetal ligands are derivatives of 1,3-benzodioxole, and while these compounds have more limited solubility, these precursors may be useful in blends for introducing various properties to the blends, such as film solubility, contact angle modulation, ion generation, and intermolecular chemistry. Applicant has developed very effective organotin patternable compositions that can be used for very high resolution patterning. Blends of organotin precursors comprising a component of the acetal ligand tin compositions can be particularly effective to improve patterning, and the blends described herein can be effective with respect to processability for positive tone patterning as well as to improve patterning results from positive tone patterning. For appropriate embodiments, the high solubility of the tin compounds with acetal ligands in aqueous developers can lower the radiation doses needed to render the blended film soluble, and the high ligand stability can extend the blended film solubility to high radiation doses, thereby improving the positive-tone processing capability. In other words, the blended film compositions comprising acetal ligands enable wider positive-tone patterning windows by improving the solubility of the irradiated material across a wider range of radiation doses.

A first step in the use of these organo tin compounds involves the synthesis of the compounds, as described further below. The as synthesized compounds or blends can used in solution or vapor deposition methods to form radiation-patternable organotin oxide hydroxide films. For the formation of compositional blends, the deposition approaches can be adjusted accordingly to realize the desired composition of the constituent components in the final deposited material. Deposition is generally achieved by hydrolysis of organotin compounds with hydrolysable ligands that are hydrolyzed during processing to form coating compositions comprising oxo and hydroxo ligands and intact organotin moieties. In the corresponding coatings, the oxo and hydroxo ligands form a network for the coating composition. The degree of condensation of the oxo-hydroxo network can be manipulated through processing, such as heating, blanket irradiation, or ambient conditions, to help guide the image processing. The solid state reactions that take place in the coatings can somewhat complex, and the complexity can be more acute for reactive species such as provided by certain ligands. Nevertheless, a basic understanding of the overall reactions can be gleaned from the data sufficiently to appreciate the manipulation to guide patterning improvement.

As demonstrated below, appropriate embodiments of the organotin compositions having acetal functionality have good solubility in a broad range of solvents and good ligand thermal stability. The broad solubility in aqueous liquids make the compositions unsuitable alone for positive tone development in aqueous base (e.g., tetramethylammonium hydroxide), and the high thermal and radiation stability of the Sn—R bonds of the acetal ligand compositions generally result in poor contrast for negative tone patterning. Nevertheless, the organotin compositions with acetal containing ligands are found to have significant utility in photoresist composition blends for positive tone patterning by extending the EUV dose process window. Some of the compositions, especially aromatic derivatives, may have utility of negative tone patterning. With respect to positive tone patterning, an extended dose process window can be useful to having sharper images following development as well as providing process flexibility. Under currently accepted IUPAC terminology usage, “acetals” is used to refer to traditionally named acetals HR¹C(OR³)(OR⁴) and ketals R¹R²C(OR³)(OR⁴). So unless specified otherwise, “acetal” shall be viewed as including traditional acetals and ketals, following current IUPAC usage. In some embodiments, the R³ and R⁴ groups are replaced with a bridging R⁵ group, forming a cyclic methylenedioxy moiety. The aromatic embodiments described, are derivatives of 1,3-benzodioxole following accepted nomenclature, although they retain a methylenedioxy moiety.

In general, acetal groups can be reactive in an appropriate environment. Evaluation of the properties of coatings formed with organotin compositions with acetal groups suggest some reactions may be taking place, but any reaction products have not been elucidated to date. The organotin compositions having radiation-sensitive acetal functionality may undergo intra- and inter-molecular reactions in response to radiation exposure and/or thermal processing, and such reactions can therefore lead to improved sensitivity. The acetal-containing organic ligands can undergo decomposition upon absorption of radiation to form unstable intermediate reactive species that can undergo further intramolecular reactions and enable subsequent Sn—C bond cleavage and ligand loss. The new ligands have acetal functionality provide for new organotin photoresist designs based on radiolysis-induced changes within the R group rather than by radiolysis-induced cleavage of the Sn—C bonds.

Organotin photoresist compositions comprising the acetal functionality can also show improved thermal stability over conventional organotin photoresists. Conventional organotin photoresists generally operate by radiolysis-induced cleavage of the Sn—C bonds wherein the material undergoes a transition from a hydrophobic carbon-rich material to a hydrophilic carbon-deficient material. Development can then be performed using an appropriate development process to result in either positive-tone or negative-tone patterning. The acetal containing ligands introduce new functionalities into the resist designs.

In the results below, the compositions with acetal ligands to tin exhibit reasonably good heat stability, which is tested by measurement of C—H vibrations as a function of a bake temperature. These results suggest relatively low radiation sensitivity. Accordingly, when used in precursor blends, the blended resists are found to maintain good solubility in positive tone developers to very high radiation doses. The blended compositions can be tailored to include a non-polar, high radiation-sensitivity organotin moiety that undergoes significant dealkylation (i.e., Sn—C bond cleavage) in response to radiation or heating, increasing the films polarity and solubility in aqueous developer while substantially preserving at high radiation doses the acetal ligand that can inhibit full condensation of the oxo network, and therefore allowing for continued solubility in aqueous solvents. Nevertheless, at the end of radiation patterning, a hard bake can complete consolidation of the composition remaining after patterning.

As used herein, and as generally consistent with usage in this field, “organotin,” “hydrocarbyl tin”, and “alkyl tin” terms can be used interchangeably, and likewise “monoalkyl” can be used interchangeably with “monoorgano” or “monohydrocarbyl”. The “alkyl” (i.e., “organo”) ligands suggest bonding to the tin via Sn—C bonds wherein the carbon is generally sp³ or sp² hybridized and forms a bond that is generally not hydrolysable through contact with water. The “alkyl” group can optionally have internal unsaturated bonds and hetero-atoms, i.e., distinct from carbon and hydrogen, that are not involved in bonding with the tin. A chemical group bonded to a metal atom is generally referred to as a ligand in the art. A reference to a “hydrolysable ligand” generally refers to a ligand bound to the Sn with a hydrolysable bond, such as an alkoxide ligand which is bound at an oxygen atom with an organo substituent on the oxygen (e.g., —OR′) or an amide ligand which is bound at a nitrogen atom with an organo substituent(s) on the nitrogen (e.g., —NR¹R²). Synthesis methods described herein yield monoalkyl tin trialkoxides in high yield and with low (non-tin) metal and polyalkyltin (i.e., polyhydrocarbyl, e.g., dialkyltin, trialkyltin) contaminants following straightforward purification. The organometallic precursor synthesis approaches are amenable for efficient scale up for commercial production, and the reactions in some embodiments can be performed as a single pot synthesis.

Organotin compounds, particularly monoalkyltin trialkoxide and triamide compounds, have found use as precursors for high-performance photoresists for EUV lithography. The use of alkyl tin compounds in high performance radiation-based patterning compositions is described, for example, in U.S. Pat. No. 9,310,684 to Meyers et al. (hereinafter the '684 patent), entitled “Organometallic Solution Based High Resolution Patterning Compositions,” incorporated herein by reference. Refinements of these organometallic compositions for patterning are described in U.S. Pat. No. 10,642,153 to Meyers et al. (hereinafter the '153 patent), entitled “Organometallic Solution Based High Resolution Patterning Compositions and Corresponding Methods,” and 10,228,618 to Meyers et al. (hereinafter the '618 patent), entitled “Organotin Oxide Hydroxide Patterning Compositions, Precursors, and Patterning,” both of which are incorporated herein by reference. In general, the monohydrocarbyl tin patterning compositions can be used for either negative tone or positive tone patterning. Nevertheless, specific ligand structures have been developed to improve specific patterning processing, such as for improved negative tone patterning. In the context of blends, some of the organotin compositions described herein can be particularly effective for forming positive tone resist compositions.

The compositions synthesized herein can be effective precursors for forming the alkyl tin oxo-hydroxo compositions that are advantageous for high resolution patterning, for example in extreme ultraviolet (EUV), ultraviolet (UV), electron-beam lithography. The alkyl tin precursor compositions comprise a group that can be hydrolyzed with water or other suitable reagent under appropriate conditions to form the monoalkyl tin oxo-hydroxo patterning compositions, which, when fully hydrolyzed, can be represented by the formula RSnO_{(1.5-(x/2))}(OH)ₓ where 0<x≤3. It can be convenient to perform the hydrolysis to form the oxo-hydroxo compositions in situ, such as during deposition and/or following initial coating formation. In other words, RSn moieties are embedded within the oxo-hydroxo network, and for blends the various RSn moieties are believed to be distributed through a common oxo-hydroxo network. While alkyl tin triamides and alkyl tin triacetylides described, for example, in the above-referenced '618 patent, can be used under hydrolyzing conditions for forming radiation sensitive coatings for patterning, it can be desirable to use alkyl tin trialkoxides as part of solution-based film-forming compositions. Direct synthesis of alkyl tin trialkoxides having ligands with acetal functional groups are described herein along with other suitable synthesis approaches.

Mono-organo (monoalkyl) tin precursor compositions can generally be represented by the formula RSnL₃, where R is an organo group (i.e., ligand) and L is a hydrolysable ligand. For processing to form radiation patternable coatings, L is generally hydrolyzed before or during or shortly after (e.g., in-situ) deposition to result in a coating comprising a polymeric organotin oxo-hydroxo composition on a substrate wherein the Sn—R bonds remain substantially intact. As a result, a radiation patternable coating having radiation-sensitive Sn—R bonds can be realized. Once the hydrolysis is completed on a substrate surface, the compositions can be considered an integrated material in which the tin atoms are distributed within an oxo-hydroxo network connecting the material. For formation of radiation patternable coatings from blends of distinct mono-organotin compositions, a similar oxo-hydroxo network is realized wherein the tin atoms having different R groups are distributed throughout the oxo-hydroxo network to form an integrated material. In this context, reorganization free energies and other collective effects can influence the individual reactivities. While solution based reactivities can provide guidance on the behavior of the compositions. reactivities in the coating may be somewhat different due to the altered environment.

### Acetal Containing Ligands

As shown in Formula 1 below, the acetal ligand compositions can generally be represented by the following formula L₃SnR¹R²C(OR³)(OR⁴), where R³ and R⁴ are independently hydrocarbyl groups having 1 to 4 carbon atoms, R² is hydrogen (traditional acetal) or a substituted or unsubstituted hydrocarbyl group having from 1 to 10 carbon atoms (traditional ketal), R¹ is a substituted or unsubstituted hydrocarbyl group having from 1 to 15 carbon atoms and a Sn—C bond, and L is a hydrolysable ligand. Formula (1) shows another depiction of the structure.

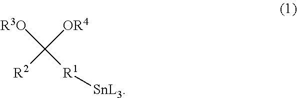

Additional acetal ligand compositions are illustrated below in Formula 2, and can be generally represented by the formula L₃SnR¹R²C(O₂R⁵), where R⁵ is a hydrocarbyl groups having 1 to 10 carbon atoms and forms a cyclic linkage between the acetal O atoms (which are known in the art as methylenedioxy functional groups), R² is hydrogen or a substituted or unsubstituted hydrocarbyl group having from 1 to 10 carbon atoms, R¹ is a substituted or unsubstituted hydrocarbyl group having from 1 to 15 carbon atoms and a Sn—C bond, and L is a hydrolysable ligand. Formula (2) provides another depiction showing the cyclic methylenedioxy structure. As used herein, the methylenedioxy structures are considered acetal structures even if aromatic.

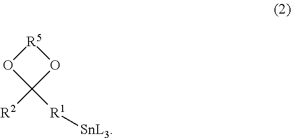

Comparing formula (1) and formula (2), R⁵ is a combination of R³ and R⁴ as a bridging group to form the resulting cyclic diether. In a sense, R⁵ represents a combination of R³ and R⁴ into a bridging structure. In some embodiments, R⁵ can comprise an aromatic group, and some embodiments of aromatic species are exemplified.

With respect to the acetal ligand tin compounds in either formula (1) or formula (2), R¹ is a substituted or unsubstituted hydrocarbyl group having from 1 to 15 carbon atoms and a Sn—C bond, in further embodiments from 1 to 10 carbon atoms, in some embodiments from 1 to 5 carbon atoms, in other embodiments from 1 to 4 carbon atoms, and in exemplified embodiments 2 or 3 carbon atoms. R² is hydrogen or a substituted or unsubstituted hydrocarbyl group having from 1 to 10 carbon atoms, in further embodiments from 1 to 5 carbon atoms, in other embodiments form 1 to 3 carbon atoms, and in exemplified embodiments, hydrogen or —CH₃. In some embodiments, R² can comprise an unsaturated hydrocarbyl group. A person of ordinary skill in the art will recognize that additional ranges of carbon atoms within the explicit ranges above are contemplated and are within the present disclosure.

If R⁵ comprises a benzene ring, the resulting structure is a 2-hydrocarbyl (R² is hydrogen) or a 2,2-dihydrocarbyl derivative of 1,3-benzodioxole, shown in the following formula:

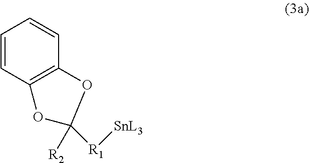

For synthesis into compositions as a tin ligand, the R¹ comprises a halide, such as a chloride group. Also, it can be desirable to halogenate the benzyl group for patterning purposes. For example, iodine has good EUV absorption, so inclusion of iodine groups can improve absorption of a resist. Fluorine groups can also be beneficial for patterning, so fluorine (—F) or trifluoromethyl (—CF₃) groups can be desirable substituents on the benzyl group. A more general formula for the 1,3-benzodioxole based ligand is:

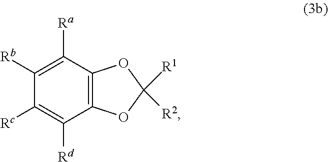

which provides for specifying substituents on the aromatic ring.

In general, the cleavage of the Sn—C bond of organotin compounds RSnL₃ can be modulated by the organic ligand R bound to the Sn. While other factors can influence the stability of the R—Sn bond, the stability of the bond generally follows the substitution of the α-carbon, i.e., the carbon directly bound to the Sn atom. In general, the stability of the Sn—C bond decreases with increasing α-carbon substitution, e.g., primary>secondary>tertiary. As the stability of the Sn—C bond increases, the dose required to cleave the bond also increases. It is therefore generally desirable for conventional organotin resists to comprise R ligands having secondary or tertiary α-carbons in order to reduce the dose needed for patterning. However, the organotin compositions with ligands having secondary and tertiary α-carbons generally tend to be more thermally unstable which can negatively affect purity, stability, and film processing.

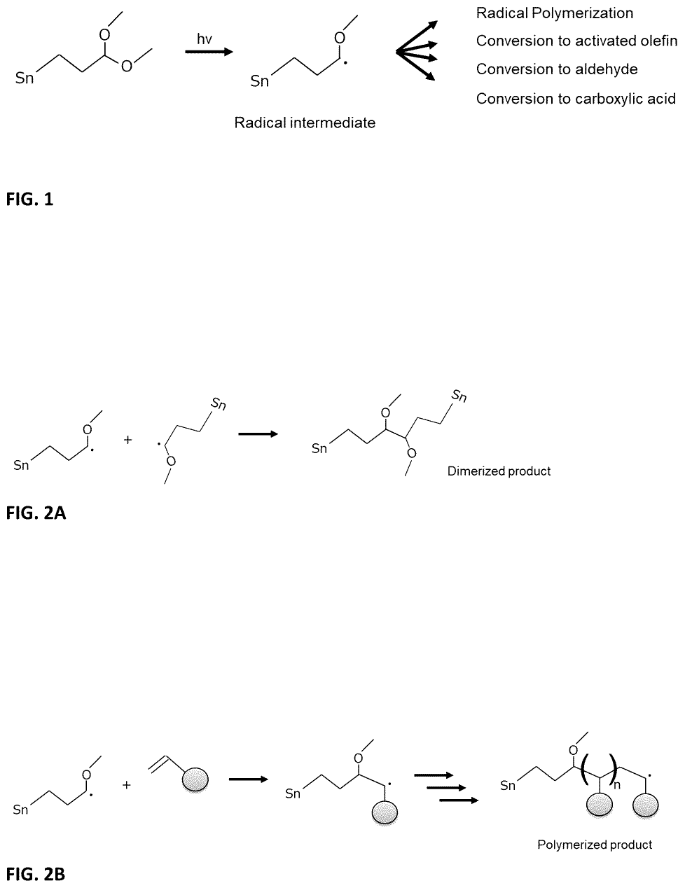

The ligands with acetal functionality described herein generally include R groups having primary α-carbons which can enhance thermal stability of the organotin resist compositions. For such compounds, R¹ in the formula above can be written as —CH₂R′, where R′ is a bond or has 1 to 14 carbon atoms. Additionally, the new organotin compositions with acetal functionality can undergo radiolysis-induced changes within the R group to create radical intermediates localized on the R group. These radical intermediates can then undergo various chemistry to form desired products that can be targeted based on appropriate selection and/or design of full ligand structure, lithographic processing conditions, and the presence of other constituents within the organotin photoresist matrix. Possible routes are illustrated in FIG. 1.

In some embodiments, it can be desirable to have ligands with fluorinated or iodinated functional groups. In particular, iodine has a relatively large EUV absorption, so the inclusion of iodine atoms can increase radiation absorption by the compositions. Ligands with iodinated aromatic groups are exemplified below. Fluorinated ligands can also be desirable. The fluorine functional groups can improve radiation absorption, potentially provide for generation of fluoride ions, and may improve thermal stability. Fluorinated and iodinated functional groups are exemplified. Halide groups, generally chloride, bromide or iodide, are also used in the synthesis pathway to form the tin carbon bonds.

In some embodiments, the ligands can also comprise unsaturated alkenyl groups. Alkenyl groups can provide some enhanced radiation absorption and may provide for crosslinking reactions to stabilize the ligand structure, which can be desirable for positive tone patterning. In particular, an alkenyl group can be included, for example, in the R² group of the ligand. One example is presented below. Organotin patterning compositions with both fluorine groups and alkene groups are described further in copending U.S. patent application Ser. No. 18/731,702 to Jilik et al., entitled “Organotin Alkoxides as Precursors for Patterning Compositions With Fluorine Substituents and Caron-Carbon Double Bonds,” incorporated herein by reference.

The chemistry of the acetal ligand organotin compositions can be predicted by the structure of the ligand containing the acetal functionality with the caveat that reaction pathways in the coating may be altered from expected solution phase reactions. The presence of the acetal functional group within the R ligand enables new chemical pathways to lithographic patterning through targeting chemical changes and/or reactions within and/or between constituents within the photoresist matrix. The results suggest that chemical changes may be taking place, but the nature of the chemical changes have not been confirmed or characterized. Instead of relying solely on contrast generated by Sn—C cleavage, the new chemical pathways allow for novel material design considerations for enabling high contrast organotin photoresist patterning. The use of precursor blends allows further exploitation of these properties due to the internal contrasts of the precursor properties. As the results below indicate, the precursor blends can extend the process window as a function of dose at both the lower dose and/or higher dose limits.

While not wanting to be limited by theory, irradiation or heating of the acetal ligand compositions can result in the formation of radical intermediates. In some embodiments, radical intermediates can undergo radical polymerization to form a crosslinked organotin film. For example, as shown in FIG. 2A, two or more radical intermediates in proximity can react to form polymerized products, which are depicted as a dimer. In some embodiments, the radical intermediates can serve as polymerization initiators in a matrix comprising other constituents having olefinic functionality. For example, as shown in FIG. 2B, the photoresist matrix can comprise a blend of different organotin compositions wherein one of the compositions comprises acetal functionality and another comprises olefinic functionality and a radical polymerization reaction can proceed to afford a polymerized organotin film.

In some embodiments, the ligands having acetal functional groups can additionally comprise a leaving group near the acetal carbon (i.e., the C atom bound to the two O atoms) such that the radical intermediates can further react to yield products having activated olefin functionality.

In some embodiments the radical intermediates can undergo intramolecular rearrangement to form unstable Sn—C bonds that can spontaneously result in Sn—C cleavage and R ligand loss. The radiation-induced chemistry of the acetal functionality can provide for an indirect non-radiative mechanism of Sn—C cleavage, and can therefore enhance the cleavage efficiency of acetal-containing R groups having primary α-carbons. By incorporation of photosensitive acetal functional groups on the ligand, the ligand can decompose upon irradiation into a reactive species which is capable of cyclization at the α-carbon to ultimately result in total ligand loss.

### Specific Acetal Ligands and Precursor Blends

In general, for positive tone patterning, the resist needs to be irradiated in order for the resist coating to be removed. The films formed from the acetal tin compounds have been found to be more broadly soluble in aqueous liquids and therefore can provide for improved positive-tone resist compositions where solubility in aqueous base is generally desired after exposure to radiation. While the coating compositions formed with these precursors alone may be ineffective as positive-tone resists, owing to their high as-deposited solubilities in aqueous bases, the blended coating compositions can be insoluble in aqueous developers without irradiation and can provide for improved positive tone patterning compared to coating compositions without acetal ligands. In general, the irradiation of organotin photoresist material renders it more hydrophilic, and therefore increases its solubility in aqueous developer. As the irradiation dose is further increased, the irradiated material undergoes extensive consolidation and densification to form insoluble tin oxide. In the examples, this transition to insolubility at higher doses is referred to as the condensation cliff. The use of blended organotin photoresist compositions comprising acetal ligands can mitigate the formation of the condensation cliff and can promote solubility of the irradiated material in aqueous developer at high doses. In some exemplified embodiments, a condensation cliff is not observed over the dose range studied. To increase the size of the process window, it is desirable to push the condensation cliff to higher doses while roughly maintaining or extending to lower doses the initial dose to achieve solubility. To perform this process adjustment, the ratio in a blend of precursor compounds and the identity of the precursor compounds can be selected accordingly.

Thus, the acetal ligands can be particularly useful in blended organotin photoresist compositions for positive-tone processing. Positive tone processing refers to a lithographic process wherein the photoresist material is rendered soluble in a developer after exposure to radiation. As described herein and in the incorporated '684 and '153 patents, with appropriate ligands, organotin photoresists can operate as both negative-tone and positive-tone photoresists depending on the developer used. In general, initially deposited organotin films suitable for positive tone patterning are insoluble in aqueous developers owing to the hydrophobic nature of the organic ligands bound to the Sn within the film. Exposure of the film to radiation severs the bonds between the organic ligands and the Sn atoms whereupon hydrophilic Sn—OH bonds can form in their place. Therefore, the unexposed coating is hydrophobic and the exposed coating is hydrophilic and the contrast between these two areas allows selective removal of either region based upon the developer used. For example, organic solvents can generally remove the unexposed regions and aqueous solvents can generally remove the exposed regions. However, as the dose increases and/or a post-exposure bake (PEB) temperature increases, the exposed regions condense further and the solubility in developer generally decreases. For negative-tone processing, the organotin resist at low doses is hydrophobic and generally soluble in organic developers until a sufficiently high dose is delivered which results in the decomposition of organic ligands and a consequent increase in hydrophilicity, rendering the exposed material insoluble in organic developer. The general material properties are similar for positive-tone processing wherein the hydrophobic organotin film is rendered more hydrophilic via exposure to radiation. At low doses, the material is hydrophobic and generally insoluble in aqueous developers. As the dose increases and more organic ligands are decomposed by radiation, the material's polarity (hydrophilicity) increases and the exposed material is rendered soluble in an aqueous developer. At sufficiently high doses, the material further condenses and the solubility of the material decreases. The range of doses for which the organotin photoresist film can be soluble in a positive-tone developer, such as an aqueous base, can be referred to as the positive-tone process window. That is, the positive-tone process window is the range of doses where positive-tone behavior is observed before the condensation cliff (i.e., extended condensation and densification) occurs that renders the material insoluble at high doses and/or process temperatures. It is generally desirable to design photoresist systems that maximize this positive-tone process window.

As noted above, the acetal ligands described herein can be useful in blended organotin compositions to improve the polarity and hydrophilicity of the photoresist film and thus improve the positive-tone process window. In general, it is desirable for an positive-tone organotin photoresists to be hydrophobic and insoluble as deposited and at low doses. Similarly, it is desirable for the condensation cliff to require as high doses as possible so that the positive-tone process window, i.e., the doses at which the organotin photoresist is soluble in an aqueous developer, can be widened. By including acetal ligands in blends of organotin photoresists, the hydrophilicity of the photoresist can be modified such that solubility in an aqueous developer can be improved. The individual components of the organotin blend, e.g., the individual organotin precursors having distinct R ligands, can be chosen such that the overall blend can be hydrophobic enough to be insoluble in aqueous base at low doses while also being resistant to extended condensation enough to maintain solubility at high doses. As found in the exemplified embodiments, relatively low proportions of acetal ligands can be effective to extend the condensation cliff to high doses.

The positive-tone organotin blends described herein comprise mixtures of organotin precursors with R groups having acetal functional groups and organotin precursors having hydrophobic R groups. The positive-tone organotin blends can generally be mixtures of organotin species represented by the formulas R^{ac}SnL₃ and RSnL′₃, wherein R is a ketal ligand and R is a substituted or unsubstituted, saturated or unsaturated, straight-chain, branched, cyclic, or aromatic hydrocarbyl group having from 1 to 30 carbon atoms. Suitable examples of R groups can include methyl, ethyl, vinyl, propyl, iso-propyl, butyl, tert-butyl, iso-butyl, butenyl, cyclopentyl, cyclohexyl, phenyl, benzyl, adamantyl, their respective isomers, heteroatom substituted, and combinations thereof. In some embodiments, the R^{ac} ligand can comprise fluorinated or iodinated species. Organotin blends can comprise independently a plurality of each type (acetal and non-acetal) ligands.

Blended precursors can be characterized by fractions of acetal precursors and non-acetal precursors. Upon deposition, the hydrolyzed coatings comprise a corresponding ratio of organo ligands. Acetal precursors and non-acetal precursors can independently be single species or blends of species, such that the ultimate blends can comprise 2 species, 3 species, 4 species, 5 species or more than 5 organotin species, but with at least one acetal species and one non-acetal species, in which each species can be characterized by an RSn moiety with a different R for each species. For vapor deposition, while in principle the compounds can be mixed, control of vapor deposition can generally be more easily accomplished with separately delivered (simultaneously and/or sequentially) compounds, due to differences in vapor pressures or boiling points, that then combine into the ultimate deposited material. In the precursor solutions, the various organotin compounds and species are present as a homogenous mixture, and the precise interactions in solution are not generally significant. Complex equilibria in the solutions are expected through hydrolysis, solvolysis, and condensation pathways and can lead to a distribution of organotin species having an overall distribution of the various RSn species corresponding to the initial ratios of distinct organotin precursors provided. Similarly, once the organotin compositions are deposited as coatings, the various RSn species are believed to be essentially randomly distributed through the resulting organotin oxo-hydroxo network.

With respect to proportions, the precursor blends generally comprise a range of acetal tin precursors from a lower limit of about 2 mole percent (mol %) or about 3 mol % or about 4 mol % or about 5 mol % any one of which to an upper limit value of about 40 mol % or about 50 mol % or about 60 mol % or about 70 mol % of acetal tin precursors relative to the total moles tin in the blend. Generally, the remainder of the organotin components are non-acetal tin precursors to result in the 100% of the organotin precursors. Specifically, the precursor blends can comprise a range of non-acetal tin precursors from a lower limit of about 30 mol %, about 40 mol %, about 50 mol %, or 60 mol % any one of which to an upper limit value of about 95 mol %, 96 mol %, 97 mol % or 98 mol %. A person of ordinary skill in the art will recognize that additional ranges of acetal in precursors and non-acetal tin precursors are contemplated and are within the present disclosure.

Selection of a particular blend can be based on the thermal and radiation responses of the particular compounds. For the improved positive tone resists described herein, it can be desirable for the acetal species to maintain solubility of the blended composition in positive tone developers out to high doses of radiation. At the same time, it is desirable for the blended composition to have little to no initial solubility in positive tone developers until a relatively low threshold dose is delivered. For such positive-tone blends, it is therefore desirable to include a non-acetal ligand (or ligands) that renders the overall blend initially insoluble in aqueous developer but that can undergo ligand cleavage at relatively low doses to result in soluble species. It is generally desirable to have relatively good thermal stability for non-irradiated material to avoid loss of contrast during the PAB or PEB processes, where such heating is desirable to facilitate solvent removal, radiation induced thermolysis, latent image condensation, and the like. The blends can balance features of the various components with these objectives in mind. For positive tone patterning, it can be desirable for the non-acetal hydrocarbyl ligand to have high radiolysis efficiency (i.e., a weaker Sn—R bond, e.g., R ligands having a secondary or tertiary α-carbon) while providing a bulky non-polar organo group that renders the blend initially insoluble in an aqueous developer. Also, it can be desirable to increase radiation absorption to improve radiolysis without necessarily correspondingly reducing thermal stability. To the extent that the acetal groups can form reactive species that maintain good solubility in positive tone developers while inhibiting full consolidation to tin oxide, which results in loss of solubility, these moieties can provide significant desirable improvement for positive tone development.

In summary, for some embodiments, positive-tone organotin resist compositions can combine polar, large, and radiolytically stable ligands (the acetal ligands) with non-polar, large, radiolytically sensitive ligands (the non-acetal ligands). Specific, non-acetal ligands of interest include, for example, cyclopentylmethyl tin (exemplified compound P3), phenyl-isopropyl (exemplified compound P1), and tert-butyl tin to give better positive tone patterning performance.

The expected advantages for these precursor blends with respect to positive tone patterning are at least threefold:
1. Large R groups frustrate formation of dense oxide formation and push the “condensation cliff” to very high doses. Positive-tone resists would be desirably fully soluble at all doses above some threshold dose (i.e., the dose-to-clear)
2. The large, non-acetal ligand in the blend grants significant hydrophobicity to the as-deposited film and consequent non-solubility of as-deposited material in positive tone resist, such as TMAH. High radiation-sensitivity enables mostly selective decomposition of this ligand during irradiation, which results in more polar species (SnR→Sn—OH) at a relatively low radiation dose that are frustrated from undergoing extensive condensation by the presence of the bulky Sn-acetal ligand, or a reaction product thereof, remaining in the coating. So exposure can drive the formation of polar (more aqueous soluble) exposed regions.
3. To achieve good positive tone patterning, an aqueous developer should wet the whole surface to dissolve the irradiated portions. One consequence of the ligand structure and the hydrophobic nature of the non-irradiated regions is that the wettability of the film suffers, which can lead to difficulties in making sure the developer can physically cover, coat, and flow across the surface of the resist composition. Blending in some of the acetal ligand moieties improves the polarity of the coating enough to improve wetting of the developer without imparting full solubility to the film. The patterning material can then have enough polarity to allow the developer to spread evenly across the surface of the wafer. Thus, precursor blends with acetal ligands can provide practical improvements to the delivery of the aqueous developer. These practical improvements can be very significant for a commercial resist product which should produce predictable results.

An advantage to organotin compositions with ligands having acetal functionality is these ligands enable new organotin photoresist compositions with high thermal stability. As described above, conventional organotin photoresists rely on radiolysis of the Sn—C bond to drive polarity differences between the exposed and unexposed material that can then extracted into physical patterns in a development process. To increase the radiolytic sensitivity of the Sn—C bond, ligands with more substituted α-carbons (e.g., R=iso-propyl, sec-butyl, tert-butyl, cyclopentylmethyl, phenyl-isopropyl, etc.) can be employed. However, increasing α-carbon substitution generally reduces the thermal stability of the Sn—C bond and a tradeoff between thermal stability and radiation sensitivity is generally observed. Thermal stability of organotin photoresists is important because it is important to localize breaking of the Sn—C bonds to within the irradiated regions of the film, and low thermal stability can result in undesired Sn—C cleavage in non-irradiated regions during routine lithographic processing, such as during a pre-development bake steps, such as a post-application bake (PAB) or a post-exposure bake (PEB). The acetal functional group compositions described herein can mitigate the tradeoff by allowing for greater radiation sensitivity without a commensurate decrease in thermal stability. R groups having more thermally stable primary α-carbons and acetal functional groups can therefore be used.

### Synthesis of Acetal Containing Ligands

For the precursor synthesis, individual precursors can be synthesized by an appropriate efficient synthesis protocol for the particular organo ligand, and the individual precursors can be blended if desired. Applicant has developed multiple synthesis protocols that are generally effective and efficient, such as with respect to cost, time, or other pragmatic factors, for a wide range of ligands for organotin precursors. With respect to versatile and efficient processes for a range of organo ligands, synthesis protocols have been discovered based on oxidative stannylation starting from Sn(II) alkoxide, and the methods offer high selectivity and efficiency. One of these approaches directly involves synthesis of an amide (—NR′₂), or an acetylide (—CCR′) hydrolysable ligands, which can be converted to alkoxide ligands. A second approach can be used to directly synthesize organotin compounds as trialkoxides. This second approach is exemplified.

The organotin compositions with ligands having acetal functional groups can be synthesized through an oxidative stannylation reaction pathway. A first of such approaches has been previously described by in published U.S. Patent Application No. 2022/0064192 entitled “Methods to Produce Organotin Compositions with Convenient Ligand Providing Reactants”, by Edson et. al and incorporated herein by reference. A typical oxidative stannylation reaction can be described as a multi-step reaction wherein the first step comprises reacting a Sn(II) compound (e.g., SnCl₂ SnBr₂, etc) with a metal (alkali, alkaline, and/or pseudo-alkaline metal) compound to form a mixed metal intermediate. The mixed metal intermediate is then reacted with an alkyl halide to form the organotin product RSnL₃, where R is a substituted or unsubstituted hydrocarbyl group having a Sn—C bond and L is a suitable hydrolysable ligand such as an amide (—NR′₂), or an acetylide (—CCR′). Overall, the reaction can be represented by the following reactions:

3 ML+SnX₂→MSnL₃+2 MX, (3)

MSnL₃+R—X→RSnL₃+MX. (4)

In some embodiments, the hydrolysable ligand L can be converted into an alkoxide. This reaction can be represented by the following reaction:

RSnL₃+R′—OH→RSn(OR′)₃+LH (5)

A similar synthesis protocol was described in published U.S. patent application 2022/0242889 to Ermert et al., entitled “Process for Preparing Organotin Compounds,” incorporated herein by reference.

In a second oxidative stannylation approach, the monoalkyltin trialkoxide is directly synthesized without needing to exchange hydrolysable ligands. This synthesis approach is described in detail in U.S. patent application 2024/0199658 to Jelik et al. (hereinafter the '658 application), entitled “Direct Synthesis of Organotin Alkoxides,” incorporated herein by reference. Specifically, and as described herein and in the Examples below, monoalkyltin trialkoxide compounds having an acetal functional group in the R group can be synthesized by the following overall reaction:

MSn(OR′)₃+RX→RSn(OR′)₃ (6)

M is generally an alkali metal, such as Li, K, Na, Cs, or Rb. R′ is generally a substituted or unsubstituted hydrocarbyl group with ≤10 carbon atoms, and OR′ can generally be selected for desirable properties of the product monoalkyltin trialkoxide, RSn(OR′)₃, such as stability, melting point, solubility, ease of purification, and so forth. In some embodiments, OR′ is tert-butoxide (OtBu). In some embodiments, OR′ is tert-amyloxide (OtAm). The '658 application describes an alternative pathway based directly on Sn(OR′)₂, bypassing the bimetallic intermediate, but this alternative is pathway results in a tin byproduct which makes it generally less desirable, although for certain ligands this alternative approach is useful.

The alkali tin trialkoxide intermediate, MSn(OR′)₃, a bimetallic alkoxide of Sn(II), has been discovered to be a useful reagent for forming organotin trialkoxides, and can be prepared according to the following reaction:

SnCl₂+3 MOR′→MSn(OR′)₃+2 MCI (7)

Unlike the dimetal compositions referenced in formula (3), the metal tin trialkoxides can be isolated and purified, although this step is not required for the synthesis of the organotin trialkoxides.

The RX compounds are selected to provide the desired alkyl ligands, R, for the organotin products. The wide availability of RX compounds as reactants as well as the broad reactivity of the compounds in the corresponding reaction provides an ability to introduce a wide range of alkyl ligands into the product monoalkyl tin products, such as alkyl ligands having acetal functional groups. For the reactions described herein, primary and secondary R groups (i.e., R groups that have a 1° or 2° C. atom that forms the C—Sn bond) can be particularly effective at forming the desired RSn(OR′)₃ compositions. X can generally be a halide chosen from I, Br, or Cl. The alkali tin alkoxide intermediate, MSn(OR′)₃, a bimetallic alkoxide of Sn(II), has been discovered to be a useful reagent for forming organotin trialkoxides, and can be prepared according to the following reaction:

Sn(OR′)₂+MOR′→MSn(OR′)₃. (8)

The alkali metal M can generally be chosen from Li, Na, K, Cs, or Rb. In some embodiments, M is K. In some embodiments, M is Li or Na. The MSn(OR′)₃ compound can be isolated, purified, and used as a solid reagent in the syntheses, and its preparation is described in detail in the '658 application. When reacted with an alkylhalide at modest temperatures and conditions, an oxidative addition reaction can occur wherein an alkyl tin bond is formed with rapid formation of alkali halide to form RSn(OR′)₃. The alkali halide salt can be alternatively filtered away, and/or the RSn(OR′)₃ product can be purified and collected via distillation.

The reactions are generally performed in dry organic solvents under an oxygen free or depleted atmosphere, such as a nitrogen-purged or argon-purged atmosphere. Solvents can be selected to result in the solubility of the various components as appropriate for the specific reactions. Due to interactions of the solvent with the metal ions, selection of solvents can be based at least in part on reaction rates in the selected solvents, which can be evaluated empirically. If different solvents are selected, they are generally miscible. Aprotic polar solvents are generally useful, such as ethers (for example, dimethyl ether, diethyl ether), tetrahydrofuran (THF), acetone, and mixtures thereof. For the alkylation steps in which the alkyl groups are bonded to the tin, nonpolar solvents are found to also be effective, such as alkanes (for example, hexane, pentane) and toluene. The solvents should generally be selected to be inert with respect to the reactants, intermediates and products. If multiple solvents are used, for example to introduce distinct reactants, the solvents should generally be miscible with respect to each other.

A catalyst comprising a halide can be present during the reaction of the bimetallic MSn(OR′)₃ compound and the hydrocarbylhalide RX compound. The catalyst can generally comprise a quaternary ammonium salt, such as tetrabutylammonium iodide, tetrabutylammonium bromide, and/or tetrabutylammonium hexafluorophosphate, and/or tetraphenylphosphonium chloride While the role of these catalysts is not completely clear, these compounds are known to act as phase transfer catalysts through helping inorganic compounds dissolve in organic solvents. Other phase transfer catalysts should be similarly useful in this context whether or not that function is directly exploited here, based on their common chemical properties. The reactions using MSn(OR′)₃ as a starting material can generally be performed in a single pot without any intermediate steps, such as separation, purification, transfer, and the like, although it is generally desirable to purify the final product.

The reactions described herein are highly selective towards formation of a monoalkyl tin trialkoxide compound, and the alkylhalide can generally be present as a reactant in a molar excess of the MSn(OR′)₃ composition. In some embodiments, the alkylhalide can be present up to about 2 mol. equivalents to the MSn(OR′)₃ compound, up to about 1.6 mol. equivalents to the MSn(OR′)₃ compound in other embodiments, up to about 1.3 mol. equivalents MSn(OR′)₃ compound in other embodiments, and up to about 1.1 mol. equivalents to the MSn(OR′)₃ compound in further embodiments. In some embodiments, the alkylhalide and the MSn(OR′)₃ compound can be present in roughly stoichiometric amounts.

In some embodiments, the reactions can generally be performed at temperatures less than about 100° C., less than about 80° C. in other embodiments, and less than 60° C. in further embodiments. In some embodiments, the reactions can be performed at room temperature. In some embodiments, the reaction can be performed under UV irradiation. In embodiments wherein visible and/or UV irradiation is performed during reaction, the reaction may or may not be heated. In some embodiments, the UV irradiation can be conducted with a wavelength of 365 nm. In some embodiments, the UV irradiation can be conducted with a wavelength on 254 nm. The reactions are generally stirred for the duration of the reaction. Efficacy of the reaction can be monitored by analyzing the reaction mixture via ¹H and/or ¹¹⁹Sn NMR to determine when the reaction has reached sufficient completion, such as a greater than about 90% yield. In some embodiments, the reactions can be performed for no more than about 5 days, for no more than about 3 days in other embodiments, for no more than about 1 day in other embodiments, and for about 1 hour to about 4 days in further embodiments. A person of ordinary skill in the art will recognize that additional ranges of time and temperature within the explicit ranges above are contemplated and are within the present disclosure. Reaction times and temperatures can generally depend on the identity of the alkylhalide (RX). Reactivity of the alkylhalide generally follows in the order of X═I>Br>Cl, and in the order of the carbon forming the C—X bond as 1°>2°>>3°. Suitable reaction times and temperatures can be determined through routine experimentation.

The above discussion focuses on the synthesis of the organotin compound with hydrolysable ligands, such as the organotin trialkoxides. These reactions involve providing the appropriate reactant to deliver the organic ligand for bonding to the tin. For the acetal containing ligands, the reactants has a structure R—X where R comprises the acetal group. In particular, for the aromatic compounds involving the benzodioxone structure, some specific synthesis pathways have been developed.

To connect R—X, where X is a halide, to the acetal ligand structures above, R ═R¹R²C(OR³)(OR⁴) or R¹R²C(—OR⁵O—). The halide (generally chlorine, although bromide or iodide may be used) is bound to R¹ at the same position at which the ligand would be bound ultimately to tin. If the carbon bound to tin is a primary carbon, then the chlorine or other halide is placed at a terminal carbon of R¹, while if the tin is bound to a secondary carbon, then the chlorine or other halide is bound to a methylene or substituted methylene carbon of R¹. Similarly, to bond tin to a tertiary carbon, the chlorine or other halide is bonded to a branch carbon. Since it is generally desirable to bond R at a primary carbon for thermal stability, it is generally desirable to have the halide for replacement at a terminal end of R¹, as used in the examples.

In general, acetal compounds and dioxolane compounds are well studied and generally available, and the desired chlorinated versions are available or can be synthesized as desired for advancing the synthesis of the organotin composition. With respect to synthesis of desired benzodioxole compounds for corresponding ligands, some synthesis techniques have been developed to facilitate forming specific derivatives. As noted above, the specific derivatives have R⁵ specified as shown above in formulas (2), (3a) and (3b). The synthesis comprises the formation of dimethoxy benzene with any desired functional groups on the benzene ring. Exemplified versions include monofluoro, diiodo, and ditrifluoromethyl derivatives on the benzene ring. Derivatizing benzene is generally well established, and derivatives are generally compatible with the remaining synthesis steps. Next, the methoxy groups are converted to hydroxyl groups using a demethylating agent, such as boron tribromide, and hydrolysis with water. The resulting dihydroxy product is reacted first with hexamethyldisilazane (HN(SiMe₃)₂, HMDS), which is included in stoichiometric or slightly greater than stoichiometric amounts. This reaction is performed with heat in toluene or other suitable organic solvent. Once the reaction is completed, the reaction solution is cooled and volatile compounds are removed by evaporation to maintain. Dichloromethane or other appropriate organic solvent is added to the intermediate and an approximate equivalent of a chlorinated aldehyde (CIR¹COH) or ketone (CIR¹COR²) is added to the reaction solution, where R¹ and R² correspond with the corresponding groups in the above formula for the benzodioxole ligands. A catalyst (trimethylsilyl trifluoromethanesulfonate) is then slowly added to activate the aldehyde or ketone and to drive the reaction to form the benzodioxole. The reaction can be continued until completion, which can be overnight. Volatiles can be removed, and a solid product can be purified by recrystallization. The purified product can then be dissolved and reacted to form the organotin compounds using the processes described above.

Once the product is formed, the organotin trialkoxides can be purified. The purification depends on the nature of the product, but generally involves the separation of the desired product from by products and potentially any unreacted reagents. Purification can generally be achieved by methods known in the art. Typical means of purification can comprise filtration, recrystallization, extraction, distillation, combinations thereof, and the like. Filtration is typically performed on a crude product mixture to remove insoluble contaminants and/or by products, for example, metal halide salts such as KI, from the solution containing the desired product. Recrystallization methods can be useful to purify solid compounds by forming, via heating, a saturated solution that then is allowed to cool. Extraction techniques can comprise, for example, liquid-liquid extractions wherein two non-miscible solvents with different densities are used to separate the desired compounds based on their relative solubilities. Purification can also comprise removal of any volatile compounds including solvents from the product mixture by drying or exposure to vacuum. For products with significant vapor pressures, which is generally the case for trialkoxides tins, it can be desirable to purify the product through vacuum distillation or, if desired, fractional distillation designed to achieve high purity. See published U.S. patent application 2020/0241413 to Clark et al., entitled “Monoalkyl Tin Trialkoxides and/or Monoalkyl Tin Triamides With Low Metal Contamination and/or Particulate Contamination and Corresponding Methods,” incorporated herein by reference. These purification techniques can be used to obtain pure products with very low non-tin metal and polyorganotin contaminants, with more than one C—Sn bond per tin atom.

### Coatings, Deposition, and Related Compositions:

The organotin precursor compositions described herein can be effectively used for radiation patterning, especially EUV patterning. The ability to have greater flexibility for ligand selection allows for further improvements in patterning results as well as designing ligands to be particularly effective for specific applications. In particular, appropriately selected precursors can be effective to improve the quality of positive tone patterning. In general, any suitable coating process can be used to deliver the precursor solution to a substrate. Suitable coating approaches can include, for example, solution deposition techniques such as spin coating, spray coating, dip coating, knife edge coating, printing, such as inkjet printing and screen printing, and the like. Many of the precursors are also suitable for vapor deposition onto a substrate as discussed in the '618 patent cited above. For some R ligand compositions and/or specific process considerations, vapor deposition may be useful for preparation of radiation sensitive coatings, which can be adapted for blended ligands through sequential or simultaneous deposition. Vapor deposition is generally performed with neat, solvent free, preparations of the precursors.

For solution deposition, after preparation of the desired organotin precursor, the precursor can be dissolved in an appropriate solvent to prepare a precursor solution, such as an organic solvent, e.g., alcohols, aromatic and aliphatic hydrocarbons, esters or combinations thereof. In particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-pentanol, 1-butanol, methanol, isopropyl alcohol, 1-propanol), ketones (e.g., methyl ethyl ketone), mixtures thereof, and the like. In general, organic solvent selection can be influenced by solubility parameters, volatility, flammability, toxicity, viscosity and potential chemical interactions with other processing materials. After the components of the solution are dissolved and combined, the character of the species may change as a result of partial in-situ hydrolysis, hydration, and/or condensation.

The organotin precursors can be dissolved in the solvent at concentrations to afford concentrations of Sn suitable for forming coatings of appropriate thickness for processing. The concentrations of the species in the precursor solutions can be selected to achieve desired physical properties of the solution. In particular, lower concentrations overall can result in desirable properties of the solution for certain coating approaches, such as spin coating, that can achieve thinner coatings using reasonable coating parameters. It can be desirable to use thinner coatings to achieve ultrafine patterning as well as to reduce material costs. In general, the concentration can be selected to be appropriate for the selected coating approach. Coating properties are described further below. In general, tin concentrations comprise from about 0.005 M to about 1.4 M, in further embodiments from about 0.02 M to about 1.2 M, and in additional embodiments from about 0.035 M to about 1.0 M. A person of ordinary skill in the art will recognize that additional ranges of tin concentrations within the explicit ranges above are contemplated and are within the present disclosure.

It has been found that controlling the water level can result in consistent and stable precursor solutions. In particular, the water level can be adjusted, generally by addition of small amounts of water to the solvent. to achieve the target water levels, generally no more than about 10,000 ppm by weight, in additional embodiments from about 100 ppm by weight to about 2500 ppm, and in further embodiments from about 200 ppm to about 1500 ppm by weight. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference.

In some embodiments, improved photosensitive precursor compositions can be present in a blended solution with one or more other organotin compositions, represented generally by the formula RSnL₃ and its hydrolysates, where R is chosen from the various moieties described in detail herein and elaborated on explicitly above. Such blended solutions can be tuned for optimization of various performance considerations, such as solution stability, coating uniformity, and patterning performance. In some embodiments, the improved photosensitive composition can comprise at least 1% by mol. Sn of a desired component in the blended solution, in further embodiments at least 10% by mol. Sn of the blended solution, in further embodiments at least 20% by mol. Sn of the blended solution, and in further embodiments at least 50% by mol. Sn of a specific desired component of the blended solution. Additional ranges of mol % of the improved photosensitive composition within the explicit ranges of the blended solution are contemplated and within the present disclosure.

Owing generally to their high vapor pressures, the organotin compositions described herein can be useful as precursors for forming coatings via vapor deposition. Vapor deposition methods generally include chemical vapor deposition (CVD), physical vapor deposition (PVD), atomic layer deposition (ALD), and modifications thereof. In a typical vapor deposition process, the organotin composition can be reacted with small molecule gas-phase reagents such as H₂O, O₂, H₂O₂, O₃, CH₃OH, HCOOH, CH₃COOH, and the like, which serve as 0 and H sources for production of radiation sensitive organotin oxide and oxide hydroxide coatings. Vapor deposition of radiation patternable organotin coatings has been described in the '618 patent cited above, as well as by Wu et. al in PCT application # PCT/US2019/031618 entitled “Methods for Making EUV Patternable Hard Masks”, incorporated herein by reference. Production of radiation sensitive organotin coatings can generally be achieved by reacting the volatile organotin precursor RSnL₃ with a small gas-phase molecule. The reactions can include hydrolysis/condensation of the organotin precursor to hydrolyze the hydrolysable ligands while leaving the Sn—C bonds substantially intact.

With respect to an outline of a representative process for a radiation-based patterning, e.g., an extreme ultraviolet (EUV) lithographic process, photoresist material is deposited or coated as a thin film on a substrate, pre-exposure (post-application) baked, exposed with a pattern of radiation to create a latent image, post-exposure baked, and then developed to convert a radiation patterned virtual image into a physical pattern. For negative tone patterning with a liquid, typically an organic solvent, the unexposed material is removed to produce a developed pattern of the resist. Negative tone patterning can also be performed with a reactive gas or other dry approaches. For positive tone patterning, a liquid, generally an aqueous liquid is contacted with the radiation patterned virtual image to remove the exposed material to form a physical pattern. Fewer steps can be used if desired, and additional steps can be used to remove residue to improve pattern fidelity.

The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 1.5 nm to 50 nm, and in further embodiments from about 2 nm to 25 nm. Those of ordinary skill in the art will understand that additional ranges of coating thickness are contemplated and are within the present disclosure.

Coating thickness for radiation patternable coatings prepared by vapor deposition techniques can generally be controlled through appropriate selection of reaction time or cycles of the process. The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 1.5 nm to 50 nm, and in further embodiments from about 2 nm to 25 nm. Those of ordinary skill in the art will understand that additional ranges of coating thickness are contemplated and are within the present disclosure.

The substrate generally presents a surface onto which the coating material can be deposited, and it may comprise a plurality of layers in which the surface relates to an upper most layer. The substrate is not particularly limited and can comprise any reasonable material such as silicon, silica, other inorganic materials, such as ceramics, and polymer materials.

After deposition and formation of the radiation patternable coating, further processing can be employed prior to exposure with radiation. In some embodiments, the coating can be heated from between 30° C. and 300° C., in further embodiments from between 50° C. and 200° C., and in further embodiments from between 80° C. and 150° C. The heating (post-application bake—PAB) can be performed, in some embodiments for about 10 seconds to about 10 minutes, in further embodiments from about 30 seconds to about 5 minutes, and in further embodiments from about 45 seconds to about 2 minutes. Additional ranges for temperatures and heating durations within the above explicit ranges are anticipated and envisioned.

### Patterning of the Compositions:

Radiation generally can be directed to the coated substrate through a mask or a radiation beam can be controllably scanned across the substrate. In general, the radiation can comprise electromagnetic radiation, an electron-beam (beta radiation), or other suitable radiation. In general, electromagnetic radiation can have a desired wavelength or range of wavelengths, such as visible radiation, ultraviolet radiation, or X-ray radiation. The resolution achievable for the radiation pattern is generally dependent on the radiation wavelength, and a higher resolution pattern generally can be achieved with shorter wavelength radiation. Thus, it can be desirable to use ultraviolet light, X-ray radiation, or an electron-beam to achieve particularly high-resolution patterns.

Following International Standard ISO 21348 (2007) incorporated herein by reference, ultraviolet light extends between wavelengths of greater than or equal to 100 nm and less than 400 30 nm. A krypton fluoride laser can be used as a source for 248 nm ultraviolet light. The ultraviolet range can be subdivided in several ways under accepted Standards, such as extreme ultraviolet (EUV) from greater than or equal 10 nm to less than 121 nm and far ultraviolet (FUV) from greater than or equal to 122 nm to less than 200 nm. A 193 nm line from an argon fluoride laser can be used as a radiation source in the FUV. EUV light at 13.5 nm has been used for lithography, and this light is generated from a Xe or Sn plasma source excited using high energy lasers or discharge pulses. Soft x-rays can be defined from greater than or equal to 0.1 nm to 5 less than 10 nm.

Based on the design of the coating material, there can be a large contrast of material properties between the irradiated regions that have condensed coating material and the unirradiated, coating material with substantially intact Sn—C bonds. For embodiments in which a post irradiation heat treatment is used, the post-irradiation heat (post-exposure bake—PEB) treatment can be performed at temperatures from about 45° C. to about 250° C., in additional embodiments from about 50° C. to about 190° C. and in further embodiments from about 60° C. to about 175° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of post-irradiation heating temperature and times within the explicit ranges above are contemplated and are within the present disclosure. This high contrast in material properties further facilitates the formation of high-resolution lines with smooth edges in the pattern following development as described in the following section.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, alcohols (e.g., 4-methyl-2-pentanol, 1-butanol, isopropanol, 1-propanol, methanol), ethyl lactate, ethers (e.g., tetrahydrofuran, dioxane, anisole), ketones (pentanone, hexanone, 2-heptanone, octanone) and the like. The development can be performed for about 5 seconds to about 30 minutes, in further embodiments from about 8 seconds to about 15 minutes and in additional embodiments from about 10 seconds to about 10 minutes. A person of ordinary skill in the art will recognize that additional ranges within the explicit ranges above are contemplated and are within the present disclosure. In addition to the primary developer composition, the developer can comprise additional compositions to facilitate the development process. Suitable additives may include, for example, viscosity modifiers, solubilization aids, or other processing aides. If the optional additives are present, the developer can comprise no more than about 10 weight percent additive and in further embodiments no more than about 5 weight percent additive. A person of ordinary skill in the art will recognize that additional ranges of additive concentrations within the explicit ranges above are contemplated and are within the present disclosure. Desirable developer compositions are described in published U.S. patent application 2020/0326627 to Jiang et al., entitled “Organometallic Photoresist Developer Compositions and Processing Methods,” incorporated herein by reference.

With a weaker developer, e.g., diluted organic developer or compositions in which the coating has a lower development rate, a higher temperature development process can be used to increase the rate of the process. With a stronger developer, the temperature of the development process can be lower to reduce the rate and/or control the kinetics of the development. In general, the temperature of the development can be adjusted between the appropriate values consistent with the volatility of the solvents. Additionally, developer with dissolved coating material near the developer-coating interface can be dispersed with ultrasonication during development. The developer can be applied to the patterned coating material using any reasonable approach. For example, the developer can be sprayed onto the patterned coating material. Also, spin coating can be used. For automated processing, a puddle method can be used involving the pouring of the developer onto the coating material in a stationary format. If desired spin rinsing and/or drying can be used to complete the development process. Suitable rinsing solutions include, for example, ultrapure water, aqueous tetraalkyl ammonium hydroxide, methyl alcohol, ethyl alcohol, propyl alcohol and combinations thereof. After the image is developed, the coating material is disposed on the substrate as a pattern.

In some embodiments, a solventless (dry) negative tone development process may be conducted through the use of an appropriate thermal development or plasma development process, such as those described by Tan et. al in PCT Pat App. No: PCT/US2020/039615 entitled “Photoresist Development With Halide Chemistries”, incorporated herein by reference. For organotin photoresist coatings, dry development can be conducted through the use of halogen-containing plasmas and gases, for example HBr and BCl₃. In some cases, dry development may offer advantages over wet development such as reduced pattern collapse, deceased scum, and fine control over developer compositions, i.e. the plasma and/or etch gases. See also, published U.S. patent application 2023/0408916 to De Schepper et al., entitled “Gas-Based Development of Organometallic Resist in an Oxidizing Halogen-Donating Environment,” incorporated herein by reference.

Specifically, for positive tone imaging, suitable developers generally can be aqueous bases. In some embodiments, aqueous bases can be used to obtain sharper images. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent.

Furthermore, mixed quaternary tetraalkyl-ammonium hydroxides can be used. In general, the developer can comprise from about 0.5 to about 30 weight percent, in further embodiments from about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure. For a positive tone developer, it can be desirable to dissolve material densified from a relatively high radiation dose, assuming that the non-irradiated material is not significantly removed. This opens up the process window further. Additional development modifications to facilitate positive tone development is described in published U.S. patent application 2024/0085785 to Kasahara et al. (hereinafter the '785 application), entitled “Additives for Metal Oxide Photoresists, Positive Tone Development With Additives, and Double Bake Double Develop Processing,” incorporated herein by reference.

The organotin resists generally can be useful for either negative tone patterning or positive tone patterning. The patterns formed with the organotin resists are not particularly limited, and can generally comprise complex layouts based on various mask patterns for device manufacturing. For testing of photoresist performance, masks comprising line/space and/or contact hole patterns can be particularly useful. In some embodiments, the patterns can be based on regularly spaced lines with patterned gaps between them (i.e., line/space patterns) or holes on a grid (i.e., contact hole patterns). The formation of holes on a grid is particularly suitable for positive tone patterning. For negative patterning of holes, the area surrounding the holes would be irradiated, in which case the holes would be subject to secondary electrons and shot noise from all sides, which makes the holes prone to having a lot of residue. As demonstrated below, positive tone patterning of holes can be performed effectively using the methods described herein.

A rinse with an inert liquid, such as deionized water, can be used to remove residual developer. After completion of the development step, the coating materials can be heat treated to further condense the material and to further dehydrate, densify, or remove residual developer or rinse from the material. This heat treatment can be particularly desirable for embodiments in which the oxide coating material is incorporated into the ultimate device, although it may be desirable to perform the heat treatment for some embodiments in which the coating material is used as a resist for pattern transfer and ultimately removed if the stabilization of the coating material is desirable to facilitate further patterning. In particular, the bake of the patterned coating material can be performed under conditions in which the patterned coating material exhibits desired levels of etch selectivity. To differentiate this heating step, this can be referred to as a hard bake. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

### EXAMPLES

### Example 1. Synthesis of 2,2-dimethoxy-5-pentyltin tris(tert-butyl oxide) (CH₃C(OMe)₂CH₂CH₂CH₂Sn(OtBu)₃)

This example describes a method for the one-pot, direct synthesis of an organotin trialkoxide with an acetal ligand.

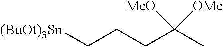

A potassium-tin trialkoxide reactant (KSn(OtBu)₃) was prepared as described in the '658 application and purified as a solid compound. The KSn(OtBu)₃ reactant, 0.4 molar equivalents (referenced to 1 molar equivalent of tin) of tetrabutylammonium iodide ((n-Bu)₄N(I)) as a catalyst, and toluene were added to a reaction vessel under inert atmosphere and mixed to form a reaction solution having a concentration of approximately 0.10 g KSn(OtBu)₃/ml toluene. The solution was mixed at room temperature. Then, 1.2 molar equivalents of 5-chloro-2,2-dimethoxypentane relative to the KSn(OtBu)₃ amount was added to the reaction solution. Then the reaction mixture was heated to 80° C. and stirred for 3 days.

Afterwards, volatiles were removed under vacuum and the remaining residue was filtered over a bed of celite with pentane. The filtrate was pumped down and distilled to afford the title compound. The identity of the product was confirmed by NMR. ¹H NMR (C₆D₆) δ 1.21 (s, 3H), 1.29 (t, 2H), 1.43 (s, 27H), 1.77+1.81 (m, 4H), 3.07 (s, 6H); ¹¹⁹Sn NMR (neat) δ −197.

This example demonstrates a method for directly synthesizing an organotin trialkoxide with an acetal group and high mono-organo specificity. No dialkyltin compounds were detected.

### Example 2. Synthesis of 2-methyl-2-(3-propyltin tris(tert-butyl oxide))1,3-dioxolane (CH₃(CO₂CH₂CH₂)CH₂CH₂CH₂Sn(OtBu)₃)

This example describes a method for the one-pot, direct synthesis of an organotin trialkoxide which has a ligand with a cyclic linkage between acetal oxygen atoms.

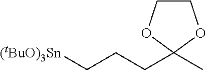

The KSn(OtBu)₃ reactant, prepared as described in Example 1, 0.5 molar equivalents of tetrabutylammonium iodide, and toluene were added to a reaction vessel under inert atmosphere and mixed to form a reaction solution having a concentration of approximately 0.10 g KSn(OtBu)₃/ml toluene. The solution was mixed at room temperature. Then, 1.0 molar equivalent of 2-methyl-2-(3-chloropropyl)-1,3-dioxolane (obtained commercially) was added to the reaction solution. Then the reaction mixture was heated to 80° C. and stirred for 3 days. Afterwards, volatiles were removed under vacuum and the remaining residue was filtered over a bed of celite with pentane. The filtrate was pumped down and distilled to afford the title compound. The identity of the product was confirmed by NMR. ¹H NMR (C₆D₆) δ 1.28 (s, 3H), 1.34 (t, 2H), 1.43 (s, 27H), 1.77 (t, 2H), 1.93 (t, 2H), 3.52 (m, 2H), 3.55 (m, 2H); ¹¹⁹Sn NMR (neat) δ −198.

This example demonstrates a method for directly synthesizing an organotin trialkoxide with a cyclic acetal group and high mono-organo specificity.

### Example 3. Synthesis of 2-(2-ethyltin tris(tert-butyl oxide))1,3-dioxolane ((CO₂CH₂CH₂)CH₂CH₂Sn(OtBu)₃)

This example describes a method for the one-pot, direct synthesis of an organotin trialkoxide which has a ligand with a cyclic linkage between acetal oxygen atoms.

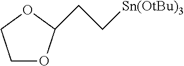

The KSn(OtBu)₃ reactant, prepared as described in Example 1, 0.2 molar equivalents of tetrabutylammonium iodide, and toluene were added to a reaction vessel under inert atmosphere and mixed to form a reaction solution having a concentration of approximately 0.10 g KSn(OtBu)₃/ml toluene. The solution was mixed at room temperature. Then, 1.1 molar equivalents of 2-(iodoethyl)-1,3-dioxolane were added to the reaction solution. Then the reaction mixture was heated to 80° C. and stirred for 3 days. Afterwards, volatiles were removed under vacuum, and the remaining residue was filtered over a bed of celite with pentane. The filtrate was pumped down and distilled to afford the title compound. The identity of the product composition was confirmed using NMR. ¹H NMR (C₆D₆) δ 1.39 (t, 2H), 1.46 (s, 27H), 2.08 (dt, 2H), 3.33 (t, 2H), 3.67 (t, 2H), 4.76 (t, 1H); ¹¹⁹Sn NMR (neat) δ −221.

This example demonstrates a method for directly synthesizing an organotin trialkoxide with a cyclic acetal group and high mono-organo specificity.

### Example 4—Synthesis of 4-((4,5-ditrifluoromethyl)benzodioxole)-pentyl tin tris(tert-butoxide)

This example describes a method for the synthesis of the fluorinated aromatic acetal organotin compound represented by the product of reaction Protocol 1. The method is based on the following synthetic strategy.

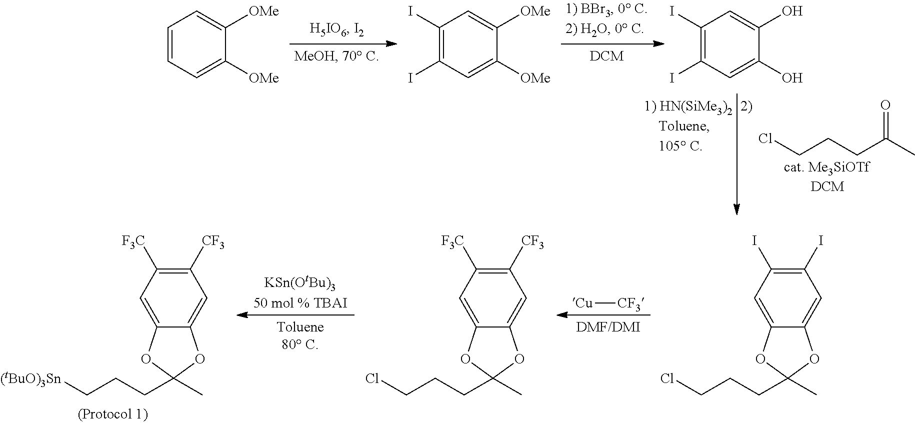

### Part A. Preparation of 1,2-diiodo-4,5-dimethoxybenzene

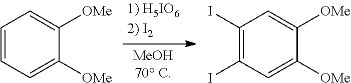 [SMILES: COc1ccccc1OC ; COc1cc(I)c(I)cc1OC]

To a pre-dried two-neck round-bottomed flask equipped with a 6-inch Vigreux column and two Schlenk adapters, H₅IO₆ (0.41 equiv.) and methanol was added. The mixture was stirred at room temperature, followed by addition of I₂ (0.8 equiv.). Under a constant stream of argon, the reaction was stirred for 10 min and 1,2-dimethoxybenzene (1 equiv.) was subsequently added via syringe. The reaction was then heated to 70° C. for 5 h. The hot solution was then poured into dilute aqueous Na₂S₂O₅ and the solution was stirred overnight. The solution was then filtered through a medium frit and the resulting solid was washed with cold methanol and subsequently dried under vacuum to yield a crystalline, colorless solid of the title compound (1,2-diiodo-4,5-dimethoxybenzene). The identity of the product composition was confirmed using NMR. ¹H NMR (400 MHz, CDCl₃): δ=7.26 (s, 2H), 3.86 (s, 6H) ppm.

### Part B. Preparation of 4,5-diiodo-1,2-benzenediol

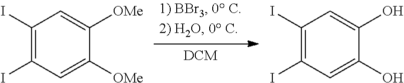 [SMILES: COc1cc(I)c(I)cc1OC ; Oc1cc(I)c(I)cc1O]

One equivalent of the product from Part A (1,2-diiodo-4,5-dimethoxybenzene) was added to a pre-dried round-bottomed flask equipped with a Schlenk adapter. The flask was then evacuated/backfilled with a constant flow of argon. Anhydrous dichloromethane (DCM) was added, and the solution was stirred and cooled to 0° C. BBr₃ (2 equiv., 1M DCM) was slowly added via cannula. The reaction was stirred at 0° C. for 4 h followed by slow addition of H₂O via an addition funnel. The solution was placed into a separatory funnel and the organics were collected. The aqueous layer was extracted with Et₂O. The organics were combined, washed sequentially with aq. Na₂S₂O₃, water, brine, then dried with MgSO₄ and filtered through a pad of silica. Volatiles were removed under reduced pressure to yield a colorless solid of the title compound (4,5-diiodo-1,2-benzenediol). The identity of the product composition was confirmed using NMR. ¹H NMR (400 MHz, CDCl₃): δ=7.37 (s, 2H), 5.23 (s, 2H) ppm.

### Part C. Preparation of 4-chloro-1-methyl (4,5-diiodo)benzodioxole

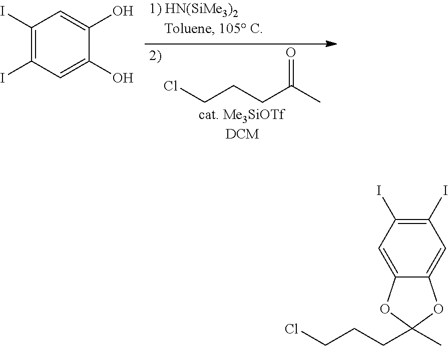

One equivalent of the product from Part B (4,5-diiodo-1,2-benzenediol) was added to a pre-dried round-bottomed flask equipped with a Schlenk adapter. The flask was then evacuated/backfilled with a constant flow of argon. Anhydrous toluene was added, followed by addition of hexamethyldisilazane (HN(SiMe₃)₂, 1.05 equiv.). The reaction mixture was then heated to 105° C. and stirred for 2 h. The temperature was then lowered to 55° C. and volatiles were removed under reduced pressure. Once evacuated, the residue was allowed to cool to room temperature and anhydrous DCM was added. The solution was stirred while 5-chloro-2-pentanone (1 equiv.) was added, followed by the slow addition of trimethylsilyl trifluoromethanesulfonate (Me₃SiOTf). The reaction mixture was sealed and stirred overnight. Then, volatiles were removed under reduced pressure and the residue was dissolved in a 5% Et₂O solution in pentane and filtered through a pad of silica. The filtrate was concentrated to yield a greasy solid. The solid was dissolved in pentane at 50° C. and then placed at −20° C. to grow crystals. The solvent was decanted from the crystals, and the crystals were washed with cold pentane. Residual pentane was then removed from the crystals under reduced pressure. The product was isolated as a crystalline, colorless solid of the title compound (4-chloro-1-methyl (4,5-diiodo)benzodioxole). The identity of the product composition was confirmed using NMR. ¹H NMR (400 MHz, CDCl₃): δ=7.25 (s, 2H), 3.58 (t, 2H), 2.11 (m, 2H), 1.94 (m, 2H), 1.64 (s, 3H) ppm.

### Part D. Preparation of 4-chloro-1-methyl (4,5-ditrifluoromethyl)benzodioxole

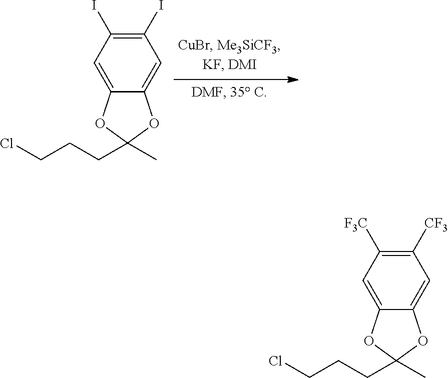 [SMILES: CC1(CCCCl)Oc2cc(I)c(I)cc2O1 ; CC1(CCCCl)Oc2cc(C(F)(F)F)c(C(F)(F)F)cc2O1]

Freshly purified copper (I) bromide (CuBr, 4.5 equiv.) was added to a pre-dried round-bottomed flask equipped with a Schlenk adapter in an argon glovebox. The flask was transferred to a Schlenk line under a constant stream of argon, where anhydrous dimethylformamide (DMF) was added via cannula followed by addition of (trifluoromethyl)trimethylsilane (Me₃SiCF₃, 3.75 equiv.) via syringe. The solution was stirred and cooled to 0° C., then potassium fluoride (KF, 3.8 equiv.) was directly added. Then, 1,3-Dimethyl-2-imidazolidinone (DMI) was added and the mixture stirred for 3 h at 0° C. Then, one equivalent of the product from Part C (4-chloro-1-methyl (4,5-diiodo)benzodioxole) was added, followed by addition of additional DMI. The reaction mixture was heated to 35° C., sealed, and stirred for at least 30 h, with the reaction progress monitored by ¹⁹F NMR spectroscopy. The reaction was allowed to proceed until the change in the area of the C—F resonances associated with the subject compound was negligible over a selected time interval, generally checking about every eight hours or after overnight. Then, Et₂O and water were added to the reaction mixture. Precipitated organics were collected. The aqueous phase was then extracted with additional Et₂O to recover additional organics. The organics were combined. The organics were washed with water, brine, then dried with MgSO₄ and filtered. The filtrate was concentrated under reduced pressure and the residue was purified via column chromatography to yield the title compound (4-chloro-1-methyl (4,5-ditrifluoromethyl)benzodioxole). The identity of the product composition was confirmed using NMR. ¹H NMR (400 MHz, CDCl₃): δ=7.19 (s, 2H), 3.59 (t, 2H), 2.19 (m, 2H), 2.00 (m, 2H), 1.73 (s, 3H) ppm. ¹⁹F NMR (282 MHz, CDCl₃): δ=−58.20 (s) ppm.

### Part E. Preparation of 4-((4,5-ditrifluoromethyl)benzodioxole)-pentyl tin tris(tert-butoxide)

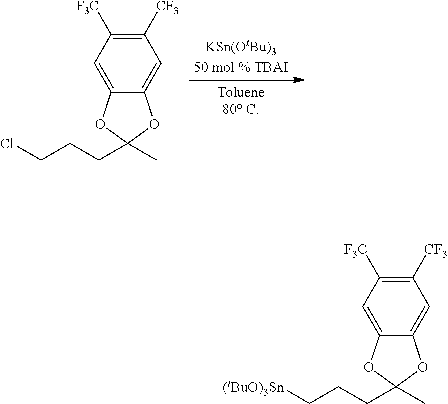

One equivalent of the product from Part D (4-chloro-1-methyl (4,5-ditrifluoromethyl)benzodioxole), 1 equivalent of potassium tin tris(tert-butoxide) (KSn(O^{t}Bu)₃, and 0.5 equivalents of tetrabutylammonium iodide (TBAI) were added to a pre-dried round-bottomed flask equipped with a Schlenk adapter in an argon glovebox. The flask is transferred to a Schlenk line under a constant stream of argon and the reaction mixture was stirred at 80° C. for at least 50 h, with the reaction progress monitored by ¹¹⁹Sn NMR spectroscopy. The reaction was allowed to proceed until the change in the area of the peak associated with the title compound was negligible. The reaction mixture was then allowed to cool to room temperature and then volatiles were removed under reduced pressure. The resulting residue was mixed with pentane and the mixture was filtered through celite. The filtrate was concentrated under reduced pressure and low-boiling impurities were removed via distillation at 90° C. (30 mTorr). The final product was distilled at 115° C. (30 mTorr) as a colorless oil of the title compound (4-((4,5-ditrifluoromethyl)benzodioxole)-pentyl tin tris(tert-butoxide)). The identity of the product composition was confirmed using NMR. ¹¹⁹Sn NMR (112 MHz, neat): δ=−197.66 (s) ppm. ¹H NMR (400 MHz, C₆D₆): δ=6.88 (s, 2H), 1.79 (m, 4H), 1.38 (s, 27H), 1.27 (s, 3H), 1.18 (t, 2H) ppm. ¹⁹F NMR (282 MHz, neat): δ=−57.90 (s) ppm.

This example described the multi-step synthesis of the fluorinated aromatic acetal organotin compound 4-((4,5-ditrifluoromethyl)benzodioxole)-pentyl tin tris(tert-butoxide).

### Example 5. Synthesis of 4-((4,5-diiodo)benzodioxole)-pentyl tin tris(tert-butoxide)

This example describes a method for the synthesis of the iodinated aromatic acetal organotin compound represented by reaction Protocol 2 from the product of Part C of Example 4. The method is based on the following reaction.

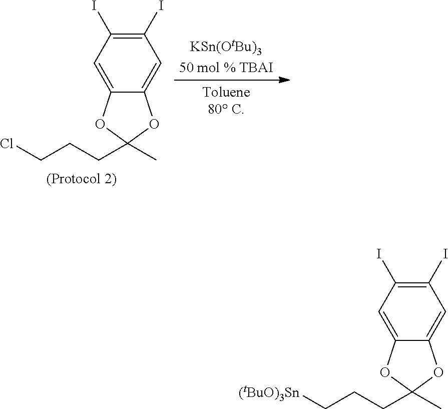

One equivalent of the product from Part C of Example 4 (4-chloro-1-methyl (4,5-diiodo)benzodioxole), 1 equivalent of potassium tin tris(tert-butoxide) (KSn(O^{t}Bu)₃), and 0.5 equivalents of tetrabutylammonium iodide (TBAI) were added to a pre-dried round-bottomed flask equipped with a Schlenk adapter in an argon glovebox. The flask was transferred to a Schlenk line under a constant stream of argon and the reaction mixture was stirred at 80° C. for at least 50 h, with the reaction progress monitored by ¹¹⁹Sn NMR spectroscopy. The reaction was allowed to proceed until the change in the area of the peak associated with the title compound was negligible. The reaction mixture was then allowed to cool to room temperature and then volatiles were removed under reduced pressure. The resulting residue was mixed with pentane and the mixture was filtered through celite. The filtrate was then concentrated under reduced pressure and low-boiling impurities were removed via distillation at 110° C. (30 mTorr) to provide the title compound (4-((4,5-diiodo)benzodioxole)-pentyl tin tris(tert-butoxide)). The identity of the product composition was confirmed using NMR. ¹¹⁹Sn NMR (112 MHz, neat): δ=−197.73 ppm. ¹H NMR (400 MHz, C₆D₆): δ=7.06 (s, 2H), 1.78 (m, 4H), 1.40 (s, 27H), 1.24 (s, 3H), 1.18 (t, 2H) ppm.

This example demonstrates a method for synthesizing an iodinated aromatic acetal organotin compound. The compound may be useful in blended compositions of organotin compositions, for example, by providing improved EUV absorption.

### Example 6. Synthesis of 2-(1-methyl-3-propyltin tris(tert-butyl oxide))1,3-(3-fluorobenzo)dioxolane (FBD)

This example describes a method for the synthesis of the fluorinated aromatic acetal organotin compound represented by formula (9).

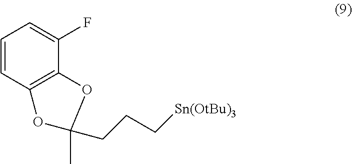

### Part A. Synthesis of 1-fluoro-2,3-bis(trimethylsiloxy)-benzene (C₆FH₃O₂(Si(CH₃)₃)₂)

3-fluorocatechol, 1 molar equivalent of hexamethyldisilazane, and toluene were added to a reaction vessel under inert atmosphere and mixed to form a reaction solution having a concentration of approximately 0.10 g 3-fluorocatechol/ml toluene. The reaction mixture was then refluxed for 3 hours. Afterwards, volatiles were removed under vacuum and the resulting oil was purified with a plug of silica, with hexanes as the eluent. The eluent was pumped down to obtain the purified product of the title compound. The identity of the product was confirmed by NMR. ¹H NMR (CDCl₃) δ 0.28 (d, 9H), 0.29 (s, 9H), 6.64 (m, 1H), 6.73 (m, 1H), 6.77 ppm (m, 1H).

### Part B. Synthesis of 2-(1-methyl-3-chloropropane)1,3-(3-fluorobenzo)dioxolane (FBD-Cl)

5-chloropropane was dissolved in dichloromethane (10 mL/g starting material) and mixed with 1 molar equivalent of the product from Part A (1-fluoro-2,3-bis(trimethylsiloxy)-benzene) and 0.17 molar equivalents of trimethylsilyl trifluoromethanesulfonate under inert atmosphere. The reaction mixture was stirred at room temperature overnight. Afterwards, volatiles were removed under vacuum and the crude oil was purified through a plug of silica with 5% diethyl ether in hexanes as the eluent. The eluent was pumped down and distilled to obtain the purified product of the title compound. The identity of the product (CH₃(CO₂C₆H₃F)CH₂CH₂CH₂Cl) was confirmed by NMR. ¹H NMR (CDCl₃) δ 1.70 (s, 3H), 2.01 (m, 2H), 2.17 (m, 2H), 3.60 (t, 2H), 6.58 (d, 1H), 6.65 (t, 1H), 6.74 ppm (m, 1H); ¹⁹F NMR (CDCl₃) −139 ppm.

### Part C. Synthesis of 2-(1-methyl-3-propyltin tris(tert-butyl oxide))1,3-(3-fluorobenzo)dioxolane (FBD)

The KSn(OtBu)₃ reactant, prepared as described in Example 1, 0.4 molar equivalents of tetrabutylammonium iodide, and toluene were added to a reaction vessel under inert atmosphere and mixed to form a reaction solution having a concentration of approximately 0.10 g KSn(OtBu)₃/ml toluene. The solution was mixed at room temperature. Then, 1.1 molar equivalent of the product from Part B (2-(1-methyl-3-chloropropane)1,3-(3-fluorobenzo)dioxolane) was added to the reaction solution. Then the reaction mixture was heated to 80° C. and stirred for 2 days. Afterwards, volatiles were removed under vacuum and the remaining residue was filtered over a bed of celite with pentane. The filtrate was pumped down and distilled to afford the title compound. The identity of the product ((CH₃(CO₂C₆H₃F)CH₂CH₂CH₂Sn(OtBu)₃) was confirmed by NMR. ¹H NMR (C₆D₆) δ 1.19 (t, 2H), 1.34 (s, 3H), 1.41 (s, 27H), 1.88 (m, 4H), 6.37 (m, 1H), 6.39 (d, 1H), 6.45 ppm (m, 1H); ¹¹⁹Sn NMR (neat) δ −200 ppm; ¹⁹F NMR (neat) δ −142 ppm.

This example described the multi-step synthesis of the fluorinated aromatic acetal organotin compound represented by the formula (CH₃(CO₂CeH₃F)CH₂CH₂CH₂Sn(OtBu)₃.

### Example 7. Synthesis of 2-(3-propyltin tris(tert-butyl oxide))-2-(1-ethenyl)-1,3-dioxolane (CH₂CH(CO₂C₂H₄)CH₂CH₂CH₂Sn(OtBu)₃)

This example describes a method for the synthesis of the unsaturated acetal organotin compound represented by formula (10).

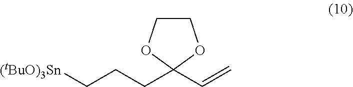

### Part A. Synthesis of 2-(3-chloropropyl)-2-(2-bromoethyl)-1,3-dioxolane (ClCH₂CH₂CH₂(CO₂CH₂CH₂)CH₂CH₂Br)

1-bromo-6-chloro-3-hexanone was synthesized using the method of Saruengkhanphasit (Rungroj Saruengkhanphasit, Darren Collier, and Iain Coldham. The Journal of Organic Chemistry 2017 82 (12), 6489-6496. DOI: 10.1021/acs.joc.7b00959), incorporated herein by reference. 1-bromo-6-chloro-3-hexanone was dissolved in toluene and mixed with ethylene glycol (1.1 equiv.) and p-toluenesulfonic acid mononhydrate (0.1 equiv.). The reaction mixture was refluxed in a Dean-Stark apparatus overnight. An aqueous workup was performed with saturated sodium bicarbonate solution and diethyl ether. Volatiles of the organic extracts were removed under vacuum and the resulting oil was purified through a silica plug with 5% diethyl ether in hexanes as the eluent. Volatiles were removed under vacuum and the product (ClCH₂CH₂CH₂(CO₂CH₂CH₂)CH₂CH₂Br) was distilled to purify. ¹H NMR (CDCl₃) δ 1.80 (m, 2H), 1.88 (m, 2H), 2.25 (t, 2H), 3.42 (t, 2H), 3.58 (t, 2H), 3.98 ppm (s, 4H).

### Part B. Synthesis of 2-(3-chloropropyl)-2-(1-ethenyl)-1,3-dioxolane (ClCH₂CH₂CH₂(CO₂CH₂CH₂)CHCH₂)

The product from Part A (2-(3-chloropropyl)-2-(2-bromoethyl)-1,3-dioxolane) was mixed with 1 molar equivalent of potassium tert-butoxide in tetrahydrofuran under inert atmosphere. The reaction mixture was stirred at room temperature for 45 minutes. Afterwards, volatiles were removed under vacuum. The identity of the product (CICH₂CH₂CH₂(CO₂CH₂CH₂)CHCH₂) was confirmed by NMR. ¹H NMR (CDCl₃) δ 1.87 (m, 4H), 3.58 (t, 2H), 3.89 (m, 2H), 3.96 (m, 2H), 5.19 (d, 1H), 5.39 (d, 1H), 5.72 ppm (dd, 1H).

### Part C. Synthesis of 2-(3-propyltin tris(tert-butyl oxide))-2-(1-ethenyl)-1,3-dioxolane (CH₂CH(CO₂C₂H₄)CH₂CH₂CH₂Sn(OtBu)₃)

The KSn(OtBu)₃ reactant, prepared as described in Example 1, 0.7 molar equivalents of tetrabutylammonium iodide, and toluene were added to a reaction vessel under inert atmosphere and mixed to form a reaction solution having a concentration of approximately 0.10 g KSn(OtBu)₃/ml toluene. The solution was mixed at room temperature. Then, 1.1 molar equivalent of the product from Part B (2-(3-chloropropyl)-2-(1-ethenyl)-1,3-dioxolane) was added to the reaction solution. Then the reaction mixture was heated to 80° C. and stirred for 4 days. Afterwards, volatiles were removed under vacuum and the remaining residue was filtered over a bed of celite with pentane. The filtrate was pumped down and distilled to afford the title compound. The identity of the product (CH₂CH(CO₂C₂H₄)CH₂CH₂CH₂Sn(OtBu)₃) was confirmed by NMR. ¹H NMR (C₆D₆) δ 1.34 (t, 2H), 1.41 (s, 27H), 1.86 (m, 2H), 1.95 (m, 2H), 3.47 (m, 2H), 3.53 (m, 2H), 5.01 (d, 1H), 5.37 (d, 1H), 5.70 ppm (dd, 1H). ¹¹⁹Sn NMR (C₆D₆) δ −197 ppm.

This example described the multi-step synthesis of the unsaturated acetal organotin compound represented by the formula CH₂CH(CO₂C₂H₄)CH₂CH₂CH₂Sn(OtBu)₃.

### Example 8: Synthesis of Hydrophobic, Bulky, Non-Ketal Ligand Organotin Precursor for Blended Precursor Coatings

### Part A: Synthesis of Phenyl Iso-propylSn(NMe₂)₃

Sn(NMe₂)₄(5.5 gm, 18.64 mmol) was dissolved in 30 ml of pentane and cumenyl potassium (3 gm, 18.83 mmol—as prepared by following the methods in Angew. Chem. Int. Ed. 2020, 59, 22460) was added slowly to the solution in several batches inside the glove box. The reaction mixture was further stirred for 2 hours at room temperature. During the reaction a tan precipitate with clear solution of pentane was generated. The precipitate was filtered over celite to yield a clear solution of pentane. Solvent was removed under vacuum and Phenyl iso-propylSn(NMe₂)₃ was obtained as colorless liquid in 43% yield. ¹¹⁹Sn NMR δ=−110.5 ppm.

### Part B: Conversion to Phenyl iso-propylSn(OtBu)₃

Phenyl iso-propylSn(NMe₂)₃ (3 gm, 3.08 mmol) was added to a flask and cooled to 0° C. tert-butanol (1.85 gm, 25.05 mmol) was added under an atmosphere of nitrogen. The reaction mixture was warmed to room temperature and stirred for 30 minutes. A colorless oil was obtained and further purified by distillation to give Phenyl iso-propylSn(O⁴Bu)₃ in 90% yield. ¹¹⁹Sn NMR (neat) δ=−231.4 ppm. ¹H NMR (400 MHz, neat) δ=7.31 (m, 2H, ArH), δ 7.11 (m, 2H, ArH), δ 6.96 (m, 1H, ArH), δ 1.59 (m, 6H, 2CH₃), δ 1.10 (m, 27H, 3C(CH₃)₃).

### Example 9. Solubility of Organotin Coatings with Acetal Ligands

This example demonstrates the preparation of coating solutions with organotin compounds having an acetal group, and the formation of hydrophilic films from the coating solutions. The solubility of the coatings following a post-application bake step was determined. Comparisons are made to organotin coatings without acetal ligands.

Coating solutions were prepared from the organotin compounds prepared in Examples 1-3. An appropriate amount of each organotin compound was dissolved in 4-methyl-2-pentanol or 1-propanol, each solvent having a water content of 300 ppm, to form the resist solutions shown in Table 1. Comparative examples were performed using Applicant's LA commercial monoalkyl tin photoresist.

TABLE 1

| | | | [Sn] |
|---|---|---|---|
| | | | Concen- |
| Resist | | | tration |
| Solution | Organotin Compound | Solvent | (M) |
| A1 | 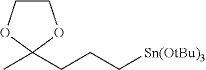 | 4-methyl-2- pentanol | 0.05 |
| A2 | 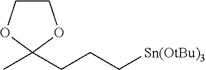 | 1-propanol | 0.05 |
| B1 | 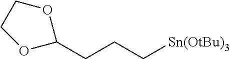 | 1-propanol | 0.05 |
| C1 | 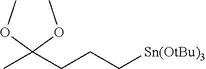 | 4-methyl-2- pentanol | 0.05 |
| C2 | 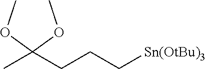 | 1-propanol | 0.05 |

Each resist precursor solution (A1-C2) was deposited via spin coating onto a separate Si wafer, prepared with a 100 nm layer of thermal oxide, to form a set of coated wafers. Following deposition, each wafer was baked at 100° C., 150° C., or 180° C. for 2 minutes (post-application bake—PAB). Each coated wafer was then dipped in a selected developer for 30 seconds and blown dry with nitrogen gas. The developed wafers were then qualitatively assessed by visual inspection and assigned values of “Y” for films that were substantially removed by the developer, “Partial” for films that were partially removed by the developer, and “N” for films that were not substantially removed by the developer. The results are shown in Table 2.

TABLE 2

| | | | Solubility | Solubility | Solubility |
|---|---|---|---|---|---|
| | Resist | | for 100° C. | for 150° C. | for 180° C. |
| Sample | Solution | Developer | PAB | PAB | PAB |
| 1 | A1 | 2-heptanone | Y | Y | Y |
| 2 | A1 | toluene | Y | Y | Y |
| 3 | A1 | PGMEA + 5 wt. % | Y | Y | Y |
| | | acetic acid | | | |
| 4 | A1 | H₂O | Partial | Partial | Partial |
| 5 | A1 | 2.38 wt. % TMAH + | Y | Partial | Partial |
| | | H₂O rinse | | | |
| 6 | A2 | 2-heptanone | Y | Y | Y |
| 7 | A2 | toluene | Y | Y | Y |
| 8 | A2 | PGMEA + 5 wt. % | Y | Y | Y |
| | | acetic acid | | | |
| 9 | A2 | H₂O | Partial | Partial | Partial |
| 10 | A2 | 2.38 wt. % TMAH + | Y | Partial | Partial |
| | | H₂O rinse | | | |
| 11 | B1 | 2-heptanone | Y | Y | Partial |
| 12 | B1 | toluene | N | N | N |
| 13 | B1 | PGMEA + 5 wt. % | Y | Partial | Partial |
| | | acetic acid | | | |
| 14 | B1 | H₂O | Y | Y | Partial |
| 15 | B1 | 2.38 wt. % TMAH + | Y | Y | Y |
| | | H₂O rinse | | | |
| 16 | C1 | 2-heptanone | Y | Y | Y |
| 17 | C1 | toluene | Y | Y | Y |
| 18 | C1 | PGMEA + 5 wt. % | Y | Y | Y |
| | | acetic acid | | | |
| 19 | C1 | H₂O | Partial | Partial | Partial |
| 20 | C1 | 2.38 wt. % TMAH + | Y | Y | Partial |
| | | H₂O rinse | | | |
| 21 | C2 | 2-heptanone | Y | Y | Y |
| 22 | C2 | toluene | Y | Y | Y |
| 23 | C2 | PGMEA + 5 wt. % | Y | Y | Y |
| | | acetic acid | | | |
| 24 | C2 | H₂O | Y | Y | Y |
| 25 | C2 | 2.38 wt. % TMAH + | Y | Y | Partial |
| | | H₂O rinse | | | |
| 26 | Comparative | H₂O | N | N | N |
| | Example | | | | |
| 27 | Comparative | 2.38 wt. % TMAH + | N | N | N |
| | Example | H₂O rinse | | | |

The results show good solubility of the films across a variety of developers. Notably, the films, derived from acetal precursors, all show at least partial solubility in water after a low temperature bake at 100° C. The results indicate that the presence of the acetal functional group imparts a high polarity to the organotin film and therefore improves solubility in water and aqueous systems. Similarly, each film shows at least partial solubility for all PAB conditions in aqueous 2.38 wt. % tetramethyl ammonium hydroxide (TMAH), further evidence of the acetal functional group imparting significant polarity and hydrophilicity to the organotin films. In comparison, an organotin coating having a non-acetal ligand (Comparative Example) showed no solubility in water or TMAH at any PAB condition.

The results suggest that the acetal ligand precursors can be useful in blended compositions for positive tone processing, which is further supported in the examples that follow.

### Example 10. Thermal Stability of Organotin Coatings with Acetal Ligands

This example describes the preparation of organotin films using an organotin precursor with ligands having acetal groups to demonstrate an increase in the thermal stability of films prepared with these precursors.

Five precursor solutions were prepared. Precursor solutions S1-S3 were formed from organotin tris (t-butoxide) precursors with ligands having acetal groups. Precursor solutions S4 and S5 were formed from organotin tris (t-butoxide) precursors with ligands absent acetal groups.

A first precursor solution (S1) was prepared by dissolving an appropriate amount of 2-methyl-2-(3-propyltin tris(tert-butyl oxide))1,3-dioxolane from Example 2 into 4-methyl-2-pentanol to form an organotin solution having an Sn concentration of 0.05 M [Sn]. A second precursor solution (S2) was prepared by dissolving an appropriate amount of 2-(2-ethyltin tris(tert-butyl oxide))1,3-dioxolane from Example 3 into 4-methyl-2-pentanol to form an organotin solution also having an Sn concentration of 0.05 M [Sn]. A third precursor solution (S3) was prepared by as described in Example 9 for resist solution C1. A fourth precursor solution (S4) was prepared by dissolving an organotin compound having a non-polar organo ligand bonded to the Sn and represented by the formula (11) into 4-methyl-2-pentanol to form an organotin solution having an Sn concentration of 0.05 M [Sn]. The organotin precursor of formula 11 was as described in Example 8. A fifth precursor solution (S5) was prepared by dissolving an organotin compound having a non-polar organo ligand bonded to the Sn and represented by the formula (12) into 1-propanol to form an organotin solution having an Sn concentration of 0.05 M [Sn]. The organotin precursor of formula (12) was synthesized through conversion of the corresponding triamide compound which was synthesized via Grignard reagent via methods described in U.S. Pat. No. 10,787,466 (herein the '466 patent) entitled “Monoalkyl tin compounds with low polyalkyl contamination, their compositions and methods” to Edson et al. and incorporated herein by reference.

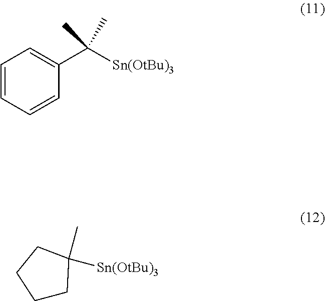

Each precursor solution (S1-S5) was spin-coated at 1500 rpm for 45 s onto a separate undoped Si wafer to produce a set of film samples (F1-F5, respectively). Each film sample had an average thickness of about 20-26 nm. Film thicknesses were measured via ellipsometry.

The coated wafers were then cleaved into approximately 1-inch chips. The chips coated with film sample F1-F5 were subjected to baking on a hotplate at a selected temperature ranging from 50° C. to 300° C. for 2 minutes or no bake.

After completion of the selected baking step for the F1-F5 film samples, the films were then analyzed via FTIR. For each sample, the sum of the peak areas between 3000 to 2850 cm⁻¹, corresponding to the alkyl C—H stretching region, was measured and normalized by dividing by the initial film thickness. The thickness normalized peak area for each of the baked films was divided by the thickness normalized peak area of the corresponding non-baked film to calculate the normalized peak area.

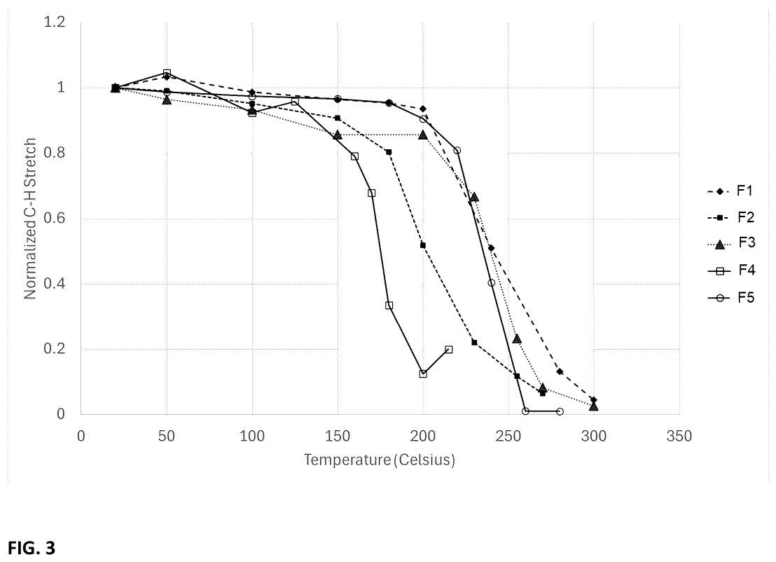

FIG. 3 shows the normalized peak area as a function of bake temperature for the film samples F1-F5. The plot's data points for the non-baked films are shown at about 0° C., which the peak areas were normalized to. The thermal stability of each ligand type (acetal versus non-acetal) was assessed by inspection of the curves in FIG. 3. At low temperatures, the FTIR results indicate a slow loss of alkyl absorption as indicated by the shallow slope of the curves. The slow loss of alkyl absorption at low temperatures is generally attributed to loss of incorporated solvent and/or film densification, although some loss due to ligand rearrangement or reaction cannot be entirely ruled out. Each sample, however, indicates a steep drop in alkyl absorption at some relatively high temperature which is attributed to thermolysis of the R—Sn bond. Decomposition temperatures for the films were qualitatively determined by identifying the temperature at which 80% of the normalized peak area is observed, and the results are presented in Table 3.

TABLE 3

| | Decomposition |
|---|---|
| Film | Temperature |
| Sample | (° C.) |
| F1 | 213 |
| F2 | 180 |
| F3 | 209 |
| F4 | 159 |
| F5 | 222 |

The FTIR results show relatively high thermal stabilities for the films having ligands with acetal groups where significant loss of C—H absorption is not seen until about 180° C. Comparatively, sample F4 shows a steep loss of C—H absorption after about 159° C. which correlates with a less thermally stable C—Sn bond. Sample F5, a non-acetal ligand compound, shows the highest thermal decomposition temperature at about 222° C. which indicates significant thermal stability of the Sn—C bond. Taken together, the results suggest the use of tailored blends between the organotin compounds having ligands with acetal groups and organotin compounds having ligands without acetal groups. Such blends can afford photoresist films having thermal stabilities amenable to a wider range of processing conditions as well as films comprising one or more components having significantly different thermal stabilities wherein selective decomposition of one ligand can be achieved.

This example demonstrated that organotin films prepared with organotin precursors having an acetal-containing ligand can have relatively high thermal stability.

### Example 11. Positive Tone Contrast Curves for Organotin Resist Blends and Controls

This example demonstrates solubilities for organotin resist coatings that are conducive to the improvement to positive-tone processing for blends comprising organotin compounds having acetal ligands.

A series of photoresist solutions were prepared from the organotin precursor compounds listed in Table 4. Compound K1 was synthesized as described in Example 2. Compound P2 was synthesized as described in the '658 application cited above. Compound P1 was synthesized as described in Example 8.

TABLE 4

| Compound | Structure |
|---|---|
| P1 | 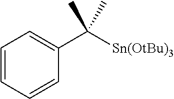 |
| P2 | 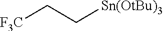 |
| K1 | 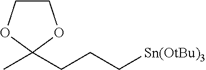 |

The compounds were combined in various ratios into a solvent blend of 38 wt. % 1-pentanol/62 wt. % 1-propanol having a total water concentration of 300 ppm to achieve solutions having a total Sn concentration of 0.038 M [Sn] and having molar ratios of P1, P2, and K1 according to Table 5.

TABLE 5

| | Mole % | Mole % | Mole % | |
|---|---|---|---|---|
| Resist | Precursor | Precursor | Precursor | Thickness |
| Solution | P1 | K1 | P2 | (nm) |
| A | 70% P1 | 30% K1 | — | 22.1 |
| B | 80% P1 | 20% K1 | — | 22.0 |
| C | 80% P1 | 10% K1 | 10% P2 | 22.3 |
| CE1 | 100% P1 | n/a | — | 21.8 |
| CE2 | 80% P1 | — | 20% P2 | 22.5 |

Resist Solutions A and B were prepared from a blend of two organotin compounds, P1 and K1. P1 has a non-polar ligand bound to tin, and K1 has a ligand with a polar, acetal functional group. Resist Solution C was prepared from a ternary mixture of P1, P2, and K1. P2 is an organotin compound having a fluorinated, non-acetal ligand. Resist Solutions CE1 and CE2 are a unary composition and a blend, respectively, of organotin compounds without acetal functional groups. The resist solutions were spin-coated onto circular 300 mm Si wafers having a layer of approximately 10 nm spin-on-glass (SOG) to form photoresist coatings. The coated wafers were then subjected to a PAB of 100° C. for 60 s. Film thicknesses, including the SOG, were measured via ellipsometry for coated wafers from each blend to give film thicknesses of 22.1 nm, 22.0 nm, 22.3 nm, 21.8 nm, and 22.5 nm for samples A, B, C, CE1, and CE2, respectively.

Following the PAB, each wafer was then exposed on an ASML TwinScan NXE3400 EUV exposure tool to create a contrast array of exposed regions (i.e., pads) across each wafer wherein each exposed region received a different dose of radiation from about 1 mJ/cm² to about 100 mJ/cm². Following EUV exposure, the films were then subjected to a post-exposure bake (PEB) of 100° C., 120° C. or 140° C. for 60 s. Development was then conducted for each wafer with 2.38 wt. % TMAH followed by a rinse with water to remove residual TMAH. Finally, the wafers received a hard bake of 250° C. for 60 s. After completion of the hard bake, contrast curves were created for each wafer by measuring the thickness of each exposed region to create the plots of thickness vs. dose for each wafer.

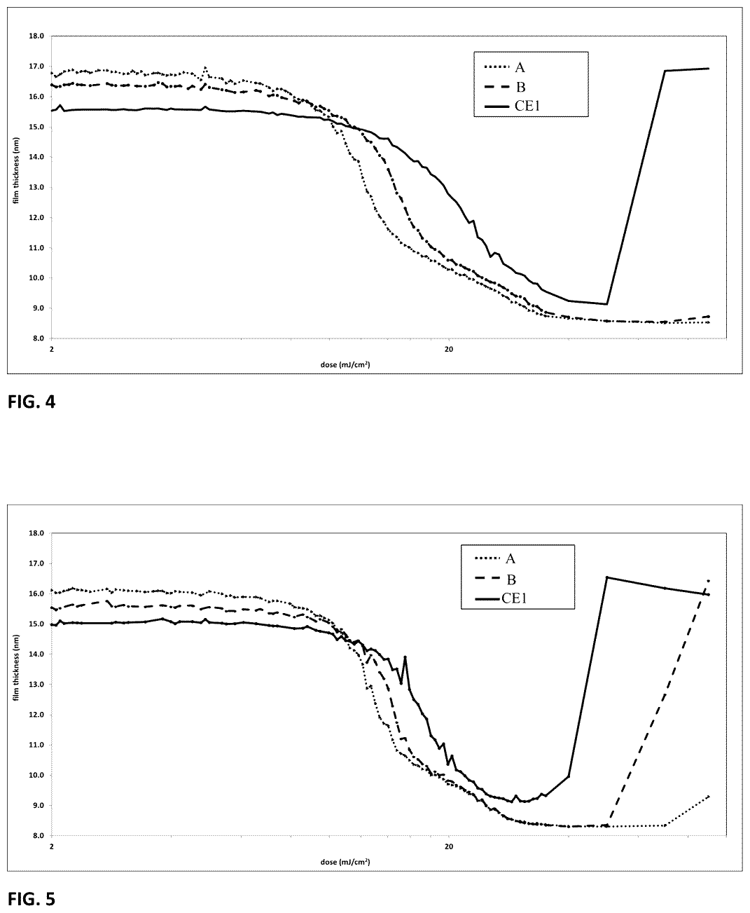

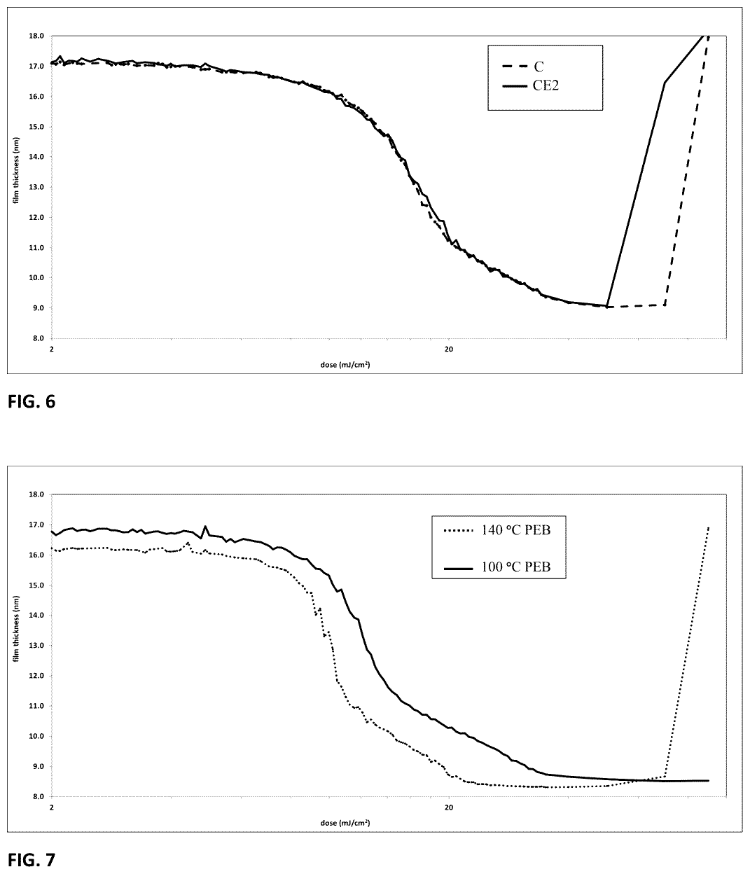

After completion of the hard bake, contrast curves were created for each wafer by measuring the thickness of each exposed region to create the plots of thickness vs. dose for each wafer. FIGS. 4 and 5 show the contrast curves for coated wafers that were prepared from Resist Solutions A, B, and CE1 and subjected to a PEB of 100° C. or 120° C., respectively. FIG. 6 shows the contrast curves for coated wafers that were prepared from Resist Solutions C and CE2 and subjected to a PEB of 100° C. FIG. 7 shows the contrast curves for coated wafers that were prepared from Resist Solution A and subjected to a PEB of 100° C. or 140° C.

Referring to FIG. 4, the wafers coated from Resist Solutions A and B showed solubility at lower positive-tone doses than the wafers coated from Resist Solution CE1. The wafers coated with Resist Solutions A and B were also absent high dose insolubility (i.e., absent a condensation cliff) up to about 90 mJ/cm², the highest EUV dose used. The results indicate that at low doses, the coatings are generally insoluble in the developer and are resistant to removal. Yet, as the radiation dose increases, sufficient hydrophobic ligands are removed from the coating material to allow for solubilizing the coating. At sufficiently high doses, the results in FIGS. 4, 5, and 6 suggest that the coatings prepared from Resist Solutions C, CE1, and CE2 undergo extensive condensation and form a condensation cliff, causing the coating to become insoluble again. The results also indicate that higher PEB temperatures can lead to the formation of a condensation cliff for compositions with ligands having acetal functional groups. Comparing FIG. 4 to FIG. 5, which show contrast curves after the wafers received a 100° C. PEB or a 120° C. PEB, respectively, Resist Sample A and B show the presence of the high-dose insoluble condensed material at a PEB of 120° C. that was not present for samples subjected to a lower PEB of 100° C. This effect is highlighted again in FIG. 7 where contrast curves generated from Resist Sample A show a condensation cliff for a PEB of 140° C. but not for a PEB of 100° C. Similar results are shown in FIG. 5 where wafers coated from Resist Solution A and B show solubility at lower positive-tone doses than for the wafers coated from Resist Solution CE1 when subjected to a higher temperature PEB of 120° C. At a 120° C. PEB (FIG. 5), the condensation cliff appears at doses lower than for a PEB of 100° C. (FIG. 4), but the coated wafers comprising the acetal ligand K1 (A and B) require higher doses for the condensation cliff to appear, effectively providing a larger positive-tine process window than for the wafers coated from Resist Solution CE1. Furthermore, the coated wafers from Resist Solution CE have a higher minimum thickness than wafers from Resist Solution A and B which indicates lower solubility of the exposure products and incomplete development which can lead to the formation of defects such as scum or microbridging.

The results also indicate that the use of higher PEB temperatures can be beneficial in reducing the positive-tone doses required for patterning. Referring to FIG. 7, adjusting the PEB from 100° C. to 140° C. results in a reduction of the dose needed to remove the resist while maintaining a large process window (range of doses) where the resist remains soluble. In comparison, FIGS. 4 and 5 show that increasing the PEB from 100° C. to 120° C. leads to a shrinking process window for Resist Sample CE1 as well as incomplete development at intermediate doses.

FIG. 6 shows contrast curves for wafers coated from Resist Solutions C and CE2, each comprising a fluorinated ligand, P2, and subjected to a PEB of 100° C. The coating prepared from Resist Solution C, a ternary blend which includes the ketal ligand compound K1, showed improvements to the positive-tone patterning over CE2 wherein the condensation cliff occurred at higher doses while maintaining similar transition at low doses.

The presence of an acetal ligand can improve the solubility of the exposed photoresist even at higher PEB temperatures, as evidenced in FIG. 7. Comparing the contrast curves collected from wafers coated from Resist Solution A and subjected to a PEB of 100° C. or 140° C., it was observed that the low dose transition can be reduced by conducting higher temperature PEBs while also achieving a wide positive tone processing window, such as by maintaining a high-dose condensation cliff.

From inspection of each contrast curve, the control samples prepared from Resist Solutions CE1 and CE2 exhibited higher low dose transitions than the samples prepared from blends incorporating the acetal-ligand organotin compound K1. Films prepared from Resist Solutions A, B, C all showed improved positive-tone process windows having both a lower transition dose and a higher dose condensation cliff as compared to either CE1 or CE2 at every PEB condition tested. The results of this study demonstrate that photoresist films prepared from a blend of an organotin precursor composition and an organotin compound having acetal ligands have improved positive-tone patterning performance due to the acetal ligands.

### Example 12. Contrast Curves Indicating Positive Tone Improvements as a Function of Hard Bake Temperatures

This example shows improvements to positive-tone patterning for organotin photoresist compositions comprising acetal R groups and the effects of hard bake.

Photoresist solutions were prepared from the compounds in Table 6. Compound K1 was synthesized as described above in Example 2. P3 was synthesized as described in Example 10 according to methods described in the '466 patent.

TABLE 6

| Compound | Structure |
|---|---|
| P3 | 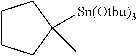 |
| K1 | 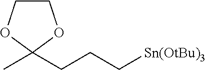 |

The compounds P3 and K1 were blended in a molar ratio of 4:1 and dissolved into an alcohol solvent blend (38 wt. % 1-pentanol/62 wt. % 1-propanol) having a total water concentration of 300 ppm to prepare a resist solution (Resist Solution D) having a total Sn concentration of 0.078 M [Sn].

A series of photoresist-coated wafers were prepared by spin-coating Resist Solution D onto circular 300 mm Si wafers having a layer of approximately 10 nm spin-on-glass (SOG). The coated wafers were then subjected to a PAB of 100° C. for 60 s. Film thicknesses were measured via ellipsometry for each wafer to be approximately 30 nm.

Following the PAB, each coated wafer was then exposed on an ASML TwinScan NXE3400 EUV exposure tool to create a contrast array of exposed regions (i.e., pads) across each wafer wherein each exposed region received a different dose of radiation from about 1 mJ/cm² to about 100 mJ/cm². Following EUV exposure, the films were then subjected to a PEB of 140° C. for 60 s. Development was then conducted for each wafer with 2.38 wt. % TMAH followed by a rinse with water to remove residual TMAH. Finally, the wafers received a 60 s hard bake (HB) at a temperature of 100° C., 150° C., 200° C., or 250° C., or none at all.

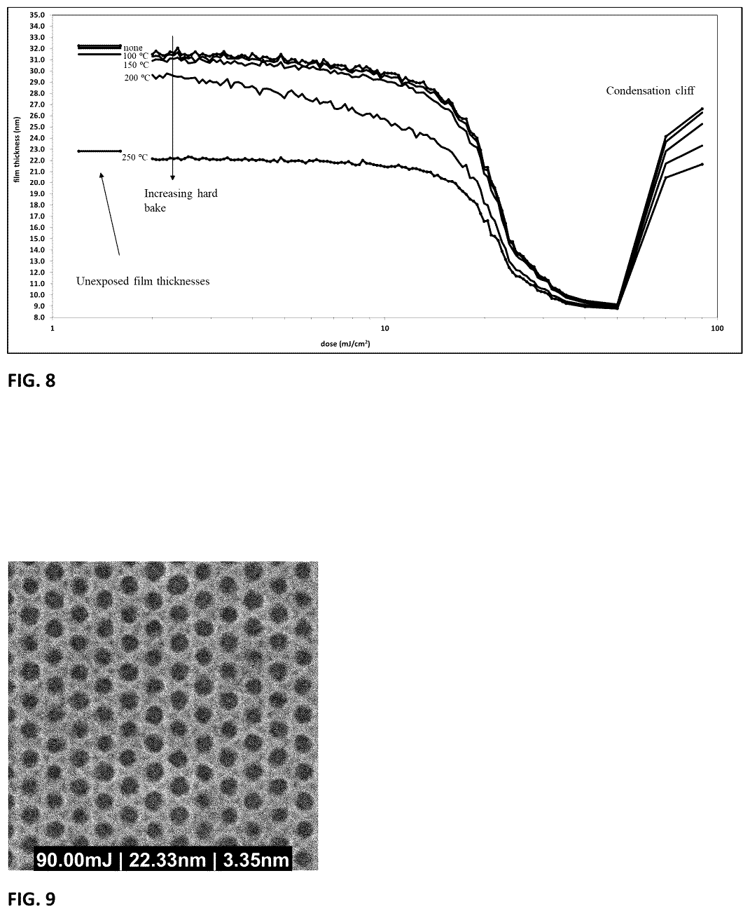

After completion of the hard bake, contrast curves were measured and plotted as described in the Example 11. FIG. 8 shows the contrast curves for the photoresist films prepared from Resist Solution D as a function of HB temperature. As the hard bake temperature increased up to 150° C., only minor variations in the contrast curves were seen. In all cases the exposed films were generally insoluble below doses of about 15 mJ/cm² and the condensation cliff is around doses of 60 mJ/cm² to give positive tone process windows of about 45 mJ/cm². For the hard bake condition of 200° C., an intermediate solubility was seen wherein the remaining thickness after development decreased more rapidly with increasing dose. This effect is attributed to a dose-dependent thermal decomposition of the organo ligands in the photoresist. Comparing the unexposed film thicknesses (represented by the lines to the left of the contrast curves) to the low dose thicknesses remaining after development, small top loss (i.e., photoresist thickness removed at low doses) is observed for most HB conditions. The more pronounced top loss observed for the 200° C. HB condition is further evidence of dose-dependent thermolysis of the organo ligands. At a hard bake of 250° C., the results suggest that the organo ligands in the photoresist have substantially decomposed as evidenced by the unexposed film thickness (about 23 nm) compared to unexposed film thickness of about 32 nm at lower HB conditions. FIG. 8 further shows that the 250° C. hard bake condition rendered the exposed photoresist material nearly completely insoluble in TMAH developer at low doses as evidenced by the small top loss observed and the near constant film thickness at doses below about 15 mJ/cm². Processing the photoresist prepared from Resist Solution D with a 250° C. hardbake was shown to provide good positive tone contrast, very little top loss, and a wide positive-tone process window. This example demonstrated the efficacy of photoresist coatings prepared with organotin blended compositions with acetal ligands for positive-tone processing.

### Example 13. Contact Hole Patterning

This example shows patterning of contact holes via positive-tone development of a blended organotin photoresist comprising an acetal ligand.

The photoresist solution described in Example 12 (Resist Solution D) was used to prepare EUV-patternable films. Resist Solution D was deposited via spin-coating onto a Si wafer pre-coated with approximately 10 nm SOG to afford a 30 nm thick photoresist coating. The coated wafer was then subjected to a PAB of 100° C. for 60 s. The wafer was then exposed using an ASML TwinScan NXE 3400 exposure tool to form hexagonal arrays of holes on a 38 nm vertical by 66 nm horizontal pitch wherein each array was printed with a different dose at different locations (i.e., fields) on the wafer. The exposed wafer was then subjected to a PEB at 140° C. for 60 seconds followed by development with 2.38 wt. % TMAH (aq). Finally, the wafer was baked at 250° C. for 1 minute to densify the patterns.

CD-SEM images were then collected using a commercial CD-SEM instrument and analyzed to determine the dose, critical dimensions (CD, the average diameter of the holes) and LCDU (local critical dimension uniformity, the standard deviation of the average CD) values for each image collected. A CD-SEM image of contact holes having a nominal CD of 22 nm is shown in FIG. 9. The contact holes were printed at a dose of 90 mJ/cm² with a measured average CD of 22.33 nm and an LCDU of 3.35 nm. The results show the ability for organotin photoresist blends comprising acetal ligands to generate high-resolution contact hole patterns at a relatively low dose.

The CD and LCDU values were comparable or lower than corresponding values those obtained with additives or a double bake double develop approach described in the '785 application.

### Further Inventive Concepts

A. A coated substrate comprising:
a substrate, and
an organotin coating on the surface of the substrate; wherein the organotin coating comprises an oxo-hydroxo network having incorporated organotin moieties represented by the formula (OR⁴)(OR³)R²CR¹Sn wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, R³ and R⁴ are independently substituted or unsubstituted hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms.
A1. The coated substrate of inventive concept A wherein the substrate comprises a semiconductor wafer.
A2. The coated substrate of inventive concept A wherein R¹ is a substituted or unsubstituted hydrocarbyl group having from 1 to 4 carbon atoms and R² is a substituted or unsubstituted hydrocarbyl group having from 1 or 2 carbon atoms.
A3. The coated substrate of inventive concept A wherein R¹ is a substituted or unsubstituted hydrocarbyl group having from 1 to 4 carbon atoms and R² is a hydrogen.
A4. The coated substrate of inventive concept A wherein R² is an unsaturated hydrocarbyl group.
A5. The coated substrate of inventive concept A wherein R³ and R⁴ are independently substituted or unsubstituted hydrocarbyl groups having 1 or 2 carbon atoms.
A6. The coated substrate of inventive concept A wherein R³ and R⁴ form a bridging structure and R⁵ is an unbranched, substituted or unsubstituted hydrocarbyl group having 2-4 carbon atoms.
A7. The coated substrate of inventive concept A wherein the oxo-hydroxo network further incorporated moieties represented by the formula R^{a}Sn, where R^{a} is a substituted or unsubstituted hydrocarbyl group having 1 to 30 carbon atom forming an C—Sn bond.
A8. The coated substrate of inventive concept A7 wherein R, is free of acetal groups and benzodioxole groups.
A9. The coated substrate of inventive concept A7 having a thickness from about 2 nm to about 40 nm.
A10. The coated substrate of inventive concept A7 wherein about 2 mol % to about 50 mol % of the C—Sn bonds correspond with (OR⁴)(OR³)R²CR¹Sn moieties.
A11. The coated substrate of inventive concept A7 wherein about 10 mol % to about mol % of the C—Sn bonds correspond with (OR⁴)(OR³)R²CR¹Sn moieties.
A12. The coated substrate of inventive concept A7 wherein the coating is insoluble in an aqueous solution of 2.38 wt % tetramethylammonium hydroxide.
A13. The coated substrate of inventive concept A7 wherein R, comprises a cyclic alkyl group, an aromatic group, a fluorinated group, an unbranched alkyl group, a branched alkyl group, or a combination thereof.
A14. The coated substrate of inventive concept A, wherein the coated substrate is formed from a precursor solution comprising:
   an organic solvent,
   a first tin precursor composition represented by the formula (OR⁴)(OR³)R²CR¹SnL₃ wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, and L is a hydrolysable ligand, and
   a second tin precursor composition represented by the formula R^{a}SnL′₃, wherein R^{a} is a substituted or unsubstituted hydrocarbyl ligand with 1 to 30 carbon atoms and an Sn—C bond, and L′ is a hydrolysable ligand that is the same or different from L.
A15. The coated substrate of inventive concept A, wherein the organotin coating has an average thickness from about 1 nm to about 50 nm.
A16. The coated substrate of inventive concept A15, wherein the organotin coating varies in thickness by no more than 25% relative to average thickness.
A17. The coated substrate of inventive concept A, wherein the Sn—C bonds that are sensitive to radiation.
A18. The coated substrate of inventive concept A, wherein the coating remains soluble in at least some polar solvents after a post-apply bake.
A19. The coated substrate of inventive concept A, wherein the coating is sensitive to EUV radiation.
B. A precursor solution for depositing a patterning composition, the precursor solution comprising:
   an organic solvent,
   a first tin precursor composition represented by the formula (OR⁴)(OR³)R²CR¹SnL₃ wherein R¹ is a substituted or unsubstituted hydrocarbyl group having from 1 to 15 carbon atoms and a Sn—C bond, R² is hydrogen or a substituted or unsubstituted hydrocarbyl group having from 1 to 10 carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, and L is a hydrolysable ligand, and
   a second tin precursor composition represented by the formula R^{a}SnL′₃, R^{a} is a substituted or unsubstituted hydrocarbyl ligand with 1 to 30 carbon atoms, and L′ is a hydrolysable ligand that is the same or different from L.
B1. The precursor solution of inventive concept B wherein the organic solvent comprises an alcohol, an aromatic hydrocarbon, an aliphatic hydrocarbon, an ester, a ketone, or a combination thereof.
B2. The precursor solution of inventive concept B wherein the organic solvent comprises 4-methyl-2-pentanol, 1-propanol, 1-pentanol, 1-butanol, methanol, isopropyl alcohol, toluene, THF, PGMEA, or a combination thereof.
B3. The precursor solution of inventive concept B wherein the molar concentration of tin is from about 0.005 M to about 1.4 M.
B4. The precursor solution of inventive concept B wherein the organic solvent comprises a controlled amount of water.
B5. The precursor solution of inventive concept B wherein R¹ is a substituted or unsubstituted hydrocarbyl group having from 1 to 4 carbon atoms and R² is a substituted or unsubstituted hydrocarbyl group having from 1 or 2 carbon atoms.
B6. The precursor solution of inventive concept B wherein R¹ is a substituted or unsubstituted hydrocarbyl group having from 1 to 4 carbon atoms and R² is a hydrogen.
B7. The precursor solution of inventive concept B wherein R² is an unsaturated hydrocarbyl group.
B8. The precursor solution of inventive concept B wherein R³ and R⁴ are independently substituted or unsubstituted hydrocarbyl groups having 1 or 2 carbon atoms.
B9. The precursor solution of inventive concept B wherein R³ and R⁴ form a bridging structure and R⁵ is an unbranched substituted or unsubstituted hydrocarbyl group having 2-4 carbon atoms.
B10. The precursor solution of inventive concept B wherein R, comprises a cyclic alkyl group, an aromatic group, a fluorinated group, an unbranched alkyl group, a branched alkyl group, or a combination thereof.
B11. The precursor solution of inventive concept B wherein R^{a}, R³, R⁴, R⁵ or a combination thereof comprise I or F groups.
B12. The precursor solution of inventive concept B wherein R, or R⁵ or both comprise an aromatic group.
B13. The precursor solution of inventive concept B12 wherein the aromatic group is iodinated or fluorinated.
B14. The precursor solution of inventive concept B wherein L and/or L′ are independently an alkoxide, a dialkylamide, an alkylacetylide, an alkylsilylamide, or a combination thereof.
B15. The precursor solution of inventive concept B wherein L and/or L′ is tert-butoxide or tert-amyloxide.
B16. The precursor solution of inventive concept B comprising from about 2 to about 50 mole % of the first tin precursor composition as a percent of the total tin content.
B17. The precursor solution of inventive concept B wherein L and L′ are alkoxy ligands.
B18. The precursor solution of inventive concept B17 wherein a deposit formed from the precursor solution under hydrolyzing conditions, following solvent removal, is substantially insoluble in 2.38 wt % aqueous tetramethyl ammonium hydroxide.
C. A method for patterning a coated substrate having a virtual image formed with patterned EUV radiation comprising a substrate and an organotin coating on the surface of the substrate, the organotin coating comprising non-irradiated portions and irradiated portions,
   wherein the non-irradiated portions comprise a patternable composition comprising an oxo-hydroxo network having incorporated organotin moieties represented by the formula (0R⁴)(OR³)R²CR¹Sn, wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, the method comprising:
   contacting the coating on the surface of the substrate with an aqueous liquid to substantially remove the irradiated portions while maintaining the non-irradiated portions substantially intact.
C1. The method of inventive concept C wherein the aqueous liquid comprises tetramethyl ammonium hydroxide.
C2. The method of inventive concept C wherein the contacting is performed using a puddle dip method.
C3. The method of inventive concept C wherein the contacting is performed using spin coating.
C4. The method of inventive concept C3 wherein after a selected period of time after the spin coating, the substrate is rinsed with an inert liquid.
C5. The method of inventive concept C wherein following removal of irradiated portions, a physical pattern is formed exposing regions of the substrate surface.
C6. The method of inventive concept C5 wherein the exposed regions are a regular pattern of holes.
C7. The method of inventive concept C5 further comprising after forming the physical pattern, heating the coated substrate in a hard bake at a temperature of at least about 175° C. for at least about 15 seconds.
D. A method for patterning a coated substrate having a virtual image formed with patterned EUV radiation comprising a substrate and an organotin coating on the surface of the substrate, the organotin coating comprising non-irradiated portions and irradiated portions,
   wherein the non-irradiated portions comprise a patternable composition comprising an oxo-hydroxo network having incorporated organotin moieties represented by the formula (0R⁴)(OR³)R²CR¹Sn, wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, R³ and R⁴ are independently hydrocarbyl groups having 1 to 4 carbon atoms or collectively form a bridging structure —OR⁵O—(R⁵=R³+R⁴) where R⁵ is a hydrocarbyl group having 1 to 10 carbon atoms and forms a cyclic linkage between the acetal O atoms, the method comprising:
   contacting the coating on the surface of the substrate with an organic liquid to substantially remove the non-irradiated portions while maintaining the irradiated portions substantially intact.
D1. The method of inventive concept D wherein the organic liquid comprises a ketone, an ester, a glycol ether, a carboxylic acid, a quaternary ammonium salt, an alcohol, or a combination thereof.
D2. The method of inventive concept D wherein the aqueous liquid comprises 2-heptanone, toluene, PGMEA, acetic acid, or a combination thereof.
D3. The method of inventive concept D further comprising rinsing with an aqueous liquid after the contacting step.
D4. The method of inventive concept D wherein the organic liquid further comprises water.
E. A method for synthesizing a substituted 1,3-benzodioxole compound, the method comprising:
   reacting a catechol in an organic solvent with hexamethylsilazne to form an intermediate; and
   reacting the intermediate in an organic solvent with a ketone or an aldehyde in the presence of trimethylsilyl trifluoromethanesulfonate catalyst to form a substituted 1,3-benzodioxole.
E2. The method of inventive concept E wherein the catechol is iodinated or fluorinated.
E3. The method of inventive concept E wherein the organic solvent comprises toluene.
E4. The method of inventive concept E wherein the ketone or aldehyde has a chloride functional group.
E5. The method of inventive concept E wherein the aldehyde or ketone is represented by the formula R¹COR², where R¹ is a substituted or unsubstituted hydrocarbyl group having from 1 to 15 carbon atoms, R² is hydrogen (aldehyde) or a substituted or unsubstituted hydrocarbyl group (ketone) having from 1 to 10 carbon atoms.
E6. The method of inventive concept E5 wherein R¹ has a halide group.
E7. The method of inventive concept E6 wherein the halide group is a terminal methyl chloride group.
E8. The method of inventive concept E6 further comprising reacting the substituted 1,3 benzodioxole with an alkali tin trialkoxide to form a substituted 1,3 benzodioxole tin trialkoxide.
E9. The method of inventive concept E8 wherein the alkali tin trialkoxide comprises a potassium tin trialkoxide.
F. A compound being a halogen substituted 2-alkyl-1,3-benzodioxole with optional additional substitutions represented by the formula C₆R^{a}R^{b}R^{c}R^{d}O₂CR¹R², wherein R¹ is a substituted or unsubstituted hydrocarbyl group having from 1 to 15 carbon atoms, R² is hydrogen or a substituted or unsubstituted hydrocarbyl group having from 1 to 10 carbon atoms.
F1. The compound of inventive concept F wherein the halogen is I or F.
F2. The composition of inventive concept F wherein R¹ is a substituted or unsubstituted hydrocarbyl group having from 1 to 4 carbon atoms and R² is a substituted or unsubstituted hydrocarbyl group having from 1 or 2 carbon atoms.
F3. The composition of inventive concept F wherein R¹ comprises a halogen group.
F4. The compound of inventive concept F3 wherein the halogen group is a terminal chloride.
F5. The compound of inventive concept F4 wherein the terminal halogenated carbon is unsaturated.
F6. The composition of inventive concept F wherein R¹ comprises an Sn—C bond.
F7. The composition of inventive concept F6 wherein R¹ comprises a tin trialkoxide group.
F8. The compound of inventive concept F wherein the compound comprises 4-chloro-1-methyl (4,5-diiodo)benzodioxole or 4-chloro-1-methyl (4,5-ditrifluoromethyl)benzodioxole.
F9. The compound of inventive concept F wherein the compound comprises 2-(1-methyl-3-propyltin tris(tert-butyl oxide))1,3-(3-fluorobenzo)dioxolane; 4-((4,5-diiodo)benzodioxole)-pentyl tin tris(tert-butoxide); or 4-((4,5-ditrifluoromethyl)benzodioxole)-pentyl tin tris(tert-butoxide).

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to measurement error for the particular parameter unless explicitly indicated otherwise.

What is claimed is:

1. A composition comprising (OR⁴)(OR³)R²CR¹SnL₃, wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, wherein R³ and R⁴ are independently substituted or unsubstituted hydrocarbyl groups having 1 to 4 carbon atoms or wherein R³ and R⁴ collectively form a bridging structure —OR⁵O—(R⁵=R³+R⁴) where R⁵ is a hydrocarbyl group having 1 to 10 carbon atoms and forms a cyclic linkage between the acetal O atoms, and L is a hydrolysable ligand.

2. The composition of claim 1 wherein R¹ is a substituted or unsubstituted hydrocarbyl group having from 1 to 4 carbon atoms and R² is a substituted or unsubstituted hydrocarbyl group having from 1 or 2 carbon atoms.

3. The composition of claim 1 wherein R¹ is a substituted or unsubstituted hydrocarbyl group having from 1 to 4 carbon atoms and R² is a hydrogen.

4. The composition of claim 1 wherein R² is an unsaturated hydrocarbyl group.

5. The composition of claim 1 wherein R³ and R⁴ are independently substituted or unsubstituted hydrocarbyl groups having 1 or 2 carbon atoms.

6. The composition of claim 1 wherein R³ and R⁴ form a bridging structure and R⁵ is an unbranched substituted or unsubstituted hydrocarbyl group having 2-4 carbon atoms.

7. The composition of claim 1 wherein L is an alkoxide, a dialkylamide, an alkylacetylide, an alkylsilylamide, or a combination thereof.

8. The composition of claim 1 wherein L is represented by —OR^{b}, where R^{b} is a hydrocarbyl group having from 1 to 15 carbon atoms.

9. The composition of claim 1 wherein L is tert-butoxide or tert-amyloxide.

10. The composition of claim 1 wherein R³, R⁴, both R³ and R⁴, or R⁵ comprise I or F groups.

11. The composition of claim 1 wherein R⁵ comprises an aromatic group.

12. The composition of claim 11 wherein the aromatic group is iodinated.

13. The composition of claim 11 wherein the aromatic group is fluorinated.

14. The composition of claim 11 wherein the aromatic group has —CF₃ functional groups.

15. The composition of claim 14 wherein the aromatic group as two —CF₃ functional groups which are bound to adjacent carbon atoms.

16. A blended composition comprising the composition of claim 1 and an organotin composition represented by the formula (R^{a})SnL′₃, or a combination thereof, and wherein R^{a} is a substituted or unsubstituted hydrocarbyl ligand with 1 to 30 carbon atoms and an Sn—C bond, and L′ is a hydrolysable ligand that is the same or different from L.

17. The blended composition of claim 16 wherein R, comprises a cyclic alkyl group, an aromatic group, a fluorinated group, an unbranched alkyl group, a branched alkyl group, or a combination thereof.

18. The blended composition of claim 16 wherein L, L′ or both are an alkoxide ligand.

19. The blended composition of claim 16 wherein R^{a} comprises a tertiary carbon bonded to Sn.

20. A precursor solution comprising a solvent and the composition of claim 1 dissolved in the solvent.

21. The precursor solution of claim 20 wherein the solvent is an alcohol.

22. The precursor solution of claim 20 having a tin concentration from about 0.005M to about 1 M.
